(19) United States
(12) Patent Application Publication
(10) Pub. No.: US 2025/0169257 A1
(43) Pub. Date: May 22, 2025

(54) DISPLAY DEVICE AND METHOD FOR MANUFACTURING THE SAME

(71) Applicant: Samsung Display Co., LTD., Yongin-si (KR)

(72) Inventor: Ki Su JIN, Yongin-si (KR)

(21) Appl. No.: 18/945,392

(22) Filed: Nov. 12, 2024

(30) Foreign Application Priority Data
Nov. 22, 2023 (KR) 10-2023-0162936

(51) Int. Cl. H01L 33/62; H01L 25/075; H01L 25/16; H01L 33/00; H01L 33/40; H01L 33/58

(52) U.S. Cl. CPC H10H 20/857; H01L 25/167; H10H 20/01; H10H 20/832; H10H 20/855; H01L 25/0753; H10H 20/0364

(57) ABSTRACT

The present disclosure relates to a display device, a method for manufacturing the same and electronic device. A light-emitting element device includes a substrate, a pixel electrode and a common electrode spaced from each other on the substrate, an organic pattern layer located between the pixel electrode and the common electrode, a light-emitting element above the organic pattern layer and including a first contact electrode and a second contact electrode above a top surface of the light-emitting element, an organic layer located in an area excluding the area where the light-emitting element is located and have a first opening and a second opening, a first conductive wall in the first opening and electrically connected to the pixel electrode, and a second conductive wall in the second opening and electrically connected to the common electrode; and a first connection electrode and a second connection electrode.

### CROSS-REFERENCE TO RELATED APPLICATION

The present application claims priority to and the benefit of Korean Patent Application No. 10-2023-0162936, filed on Nov. 22, 2023, in the Korean Intellectual Property Office, the entire disclosure of which is incorporated by reference herein.

### BACKGROUND

### 1. Field

The present disclosure relates to a display device, a method for manufacturing the same and electronic device.

### 2. Description of the Related Art

With the development of the information society, the demand for display devices for displaying images is increasing in various forms. The display device may be a flat panel display such as a liquid crystal display, a field emission display, a light-emitting display, and/or the like. The light-emitting display device may include an organic light-emitting display device including an organic light-emitting diode (OLED) element as a light-emitting element, and a miniature light-emitting display device including a micro light-emitting diode element (hereinafter referred to as a micro light-emitting element) as a light-emitting element.

In particular, as display devices become smaller and thinner, inorganic light-emitting elements are being widely used as light-emitting devices.

Generally, a light-emitting element using an inorganic material is grown on a growth substrate, and the grown light-emitting element is separated from the growth substrate and transferred to a transistor substrate. At this time, the light-emitting element may be bonded to the pixel electrode and the common electrode of the substrate using a connecting electrode. If the connection electrode is bent excessively during the bonding process, disconnection of the connection electrode may occur, causing the light-emitting element to not emit light.

### SUMMARY

Aspects of embodiments of the present disclosure provide a display device and a manufacturing method thereof that may reduce or prevent a case of non-emission light-emitting elements due to disconnection of connection electrodes.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a light-emitting element device includes: a substrate; a pixel electrode and a common electrode spaced from each other on the substrate; an organic pattern layer between the pixel electrode and the common electrode; a light-emitting element above the organic pattern layer and including a first contact electrode and a second contact electrode on a top surface of the light-emitting element; an organic layer located in an area excluding an area where the light-emitting element is located and have a first opening and a second opening; a first conductive wall in the first opening, and electrically connected to the pixel electrode; a second conductive wall in the second opening, and electrically connected to the common electrode; and a first connection electrode connected to the first contact electrode of the light-emitting element and the first conductive wall, and a second connection electrode connected to the second contact electrode of the light-emitting element and the second conductive wall.

The light-emitting element device further includes: a bank covering edges of the pixel electrode and the common electrode and in an area excluding an area where the organic pattern layer is located; a first auxiliary electrode extending from the pixel electrode above a top surface of the bank; and a second auxiliary electrode extending from the common electrode above the top surface of the bank, wherein the first opening exposes the first auxiliary electrode, and wherein the second opening exposes the second auxiliary electrode.

The first conductive wall is in contact with the first auxiliary electrode through the first opening, and the second conductive wall is in contact with the second auxiliary electrode through the second opening.

The first conductive wall and the second conductive wall include a light-blocking material.

The first conductive wall overlaps a first side of the light-emitting element, and the first side of the light-emitting element completely overlaps the first conductive wall, wherein the second conductive wall overlaps a second side of the light-emitting element, and the second side of the light-emitting element completely overlaps the second conductive wall, and wherein the first side and the second side are parallel to each other.

A width of the first conductive wall is greater than a width of the first side of the light-emitting element, and wherein a width of the second conductive wall is greater than a width of the second side of the light-emitting element.

The first conductive wall overlaps a third side of the light-emitting element and is spaced from the second conductive wall, wherein the second conductive wall overlaps a fourth side of the light-emitting element and is spaced from the first conductive wall, and wherein the third side is substantially perpendicular to the first side and parallel to the fourth side.

The light-emitting element device further including: a third conductive wall that overlaps a third side of the light-emitting element, and that is spaced from the first conductive wall and the second conductive wall, and a fourth conductive wall that overlaps a fourth side of the light-emitting element, and that is spaced from the first conductive wall and the second conductive wall, wherein the third side of the light-emitting element completely overlaps the third conductive wall, wherein the fourth side of the light-emitting element completely overlaps the fourth conductive wall, and wherein the third side is substantially perpendicular to the first side and parallel to the fourth side.

The light-emitting element further includes a third semiconductor layer, a second semiconductor layer, an active layer, a first semiconductor layer, and a protective layer, wherein the third semiconductor layer is in contact with the organic pattern layer, and wherein the protective layer is on an entire surface of the light-emitting element, excluding a bottom of the light-emitting element, and defines an opening exposing the first contact electrode and the second contact electrode on the top surface of the light-emitting element.

The pixel electrode and the common electrode include an opaque metal material, and wherein the first connection electrode and the second connection electrode include a transparent conductive oxide.

A width of the organic pattern layer is greater than a width of the light-emitting element.

The light-emitting element device further includes: a light-blocking layer on the first connection electrode and the second connection electrode, overlapping the bank, and defining a light-emitting area; and a wavelength conversion layer or a light transmission layer in a space defined by the light-blocking layer.

The light-emitting element device further includes a capping layer, an overcoat layer, and a color filter layer sequentially above the wavelength conversion layer and the light-blocking layer.

According to one or more embodiments, a method of manufacturing a display device includes: forming a pixel electrode and a common electrode spaced from each other on a substrate; forming a bank defining an opening exposing a portion of the pixel electrode and the common electrode; forming a first auxiliary electrode above a top surface of the bank along the opening on a top surface of the pixel electrode; forming a second auxiliary electrode above the top surface of the bank along the opening on a top surface of the common electrode; forming an organic pattern layer between the first auxiliary electrode and the second auxiliary electrode; bonding a light-emitting element on the organic pattern layer; exposing a first contact electrode and a second contact electrode above a top surface of the light-emitting element; flattening the light-emitting element, forming an organic layer defining a first opening exposing the first auxiliary electrode, and a second opening exposing the second auxiliary electrode; forming a first conductive wall by filling the first opening with a conductive material; forming a second conductive wall by filling the second opening with the conductive material; forming a first connection electrode connected to the first contact electrode of the light-emitting element and the first conductive wall; and forming a second connection electrode connected to the second contact electrode of the light-emitting element and the second conductive wall.

The conductive material further includes a light-blocking material.

A width of the first conductive wall is greater than a width of a first side of the light-emitting element, and wherein a width of the second conductive wall is greater than a width of a second side of the light-emitting element.

The pixel electrode and the common electrode include an opaque metal material, and wherein the first connection electrode and the second connection electrode include a transparent conductive oxide.

The method further includes: forming a light-blocking layer on the bank; forming a first wavelength conversion layer in an area corresponding to a first sub-pixel of the display device; forming a second wavelength conversion layer in an area corresponding to a second sub-pixel of the display device; forming a light transmission layer in an area corresponding to a third sub-pixel of the display device from among the areas partitioned by the light-blocking layer; forming a first color filter on the first wavelength conversion layer; forming a second color filter on the second wavelength conversion layer; and forming a third color filter on the light transmission layer.

The bonding the light-emitting element on the organic pattern layer further includes curing the organic pattern layer in the opening at a first temperature; inserting a portion of each of the light-emitting elements into the organic pattern layer at the opening; and curing the organic pattern layer at a second temperature higher than the first temperature.

The light-emitting element further includes a third semiconductor layer, a second semiconductor layer, an active layer, a first semiconductor layer, and a protective layer, and wherein the third semiconductor layer is inserted into the organic pattern layer.

According to a display device and a method of manufacturing the same according to one or more embodiments, it is possible to reduce or prevent a case of non-emission of light from the light-emitting element due to disconnection of the connection electrode.

According to one or more embodiments, electronic device includes a display device comprising a light-emitting elements and displays an image, the light-emitting elements includes, a substrate; a pixel electrode and a common electrode spaced from each other on the substrate; an organic pattern layer between the pixel electrode and the common electrode; a light-emitting element above the organic pattern layer and including a first contact electrode and a second contact electrode on a top surface of the light-emitting element; an organic layer located in an area excluding an area where the light-emitting element is located and have a first opening and a second opening; a first conductive wall in the first opening, and electrically connected to the pixel electrode; a second conductive wall in the second opening, and electrically connected to the common electrode; and a first connection electrode connected to the first contact electrode of the light-emitting element and the first conductive wall, and a second connection electrode connected to the second contact electrode of the light-emitting element and the second conductive wall.

However, the aspects of the present disclosure are not limited to the aforementioned effects, and various other aspects are included in the present disclosure.

### BRIEF DESCRIPTION OF THE DRAWINGS

FIG. 1 is a perspective view illustrating a display device according to one or more embodiments.

FIG. 2 is a layout diagram illustrating a display device according to one or more embodiments.

FIG. 3 is a block diagram illustrating a display device according to one or more embodiments.

FIG. 4 is an equivalent circuit diagram illustrating a sub-pixel according to one or more embodiments.

FIG. 5 is an equivalent circuit diagram illustrating a sub-pixel according to one or more embodiments.

FIG. 6 is a layout diagram illustrating a plurality of pixels in a display area according to one or more embodiments.

FIG. 7 is a layout diagram illustrating one example of an area A of FIG. 6 in detail.

FIG. 8 is a cross-sectional view illustrating an example of a cross-section of a display panel corresponding to the lines 11-11′, 12-12′, and 14-14 of FIG. 6.

FIG. 9 is an enlarged view of the connection structure of the light-emitting element LE of the first sub-pixel SPX1 of FIG. 8.

FIG. 10 is a plan view illustrating the light-emitting element, conductive wall, pixel electrode, common electrode, and connection electrode of FIG. 9.

FIG. 11 is one or more other embodiments of FIG. 10.

FIG. 12 is one or more other embodiments of FIG. 10.

FIG. 13 is a flowchart illustrating a method of manufacturing a display device according to one or more embodiments.

FIGS. 14-22 are cross-sectional views to illustrate a method of manufacturing a display device according to one or more embodiments.

FIG. 23 shows a virtual reality device including a display device according to one or more embodiments.

FIG. 24 shows a smart device including a display device according to one or more embodiments.

FIG. 25 shows a vehicle including a display device according to one or more embodiments.

FIG. 26 shows a transparent display device including a display device according to one or more embodiments.

### DETAILED DESCRIPTION

Aspects of embodiments of the present disclosure and methods of accomplishing the same may be understood more readily by reference to the detailed description of embodiments and the accompanying drawings. The described embodiments are provided as examples so that the present disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The embodiments may have various modifications and may be embodied in different forms, and should not be construed as being limited to only the illustrated embodiments herein. The present disclosure covers all modifications, equivalents, and/or replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and/or regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

One or more embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, and/or regions, but are to include deviations in shapes that result from, for instance, manufacturing.

For example, an implanted region illustrated as a rectangle will, typically, have rounded and/or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements and/or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component and/or intervening layers, regions, and/or components may be present. However, “directly connected/directly coupled,” or “directly on,” refers to one component directly connecting or coupling another component, or being on another component, without an intermediate component.

In addition, in the present disclosure, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, and/or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of the present disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, and/or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, and/or portion from another element, member, component, region, area, layer, section, and/or portion. Thus, a first element, component, region, layer, and/or section described below could be termed a second element, component, region, layer, and/or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and/or “including,” when used in the present disclosure, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” and/or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present disclosure, and should not be interpreted in an idealized or overly formal sense, unless expressly so defined herein.

Hereinafter, embodiments will be described with reference to the attached drawings.

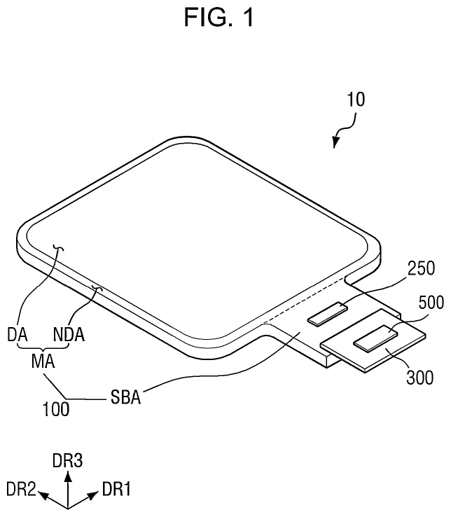

FIG. 1 is a perspective view illustrating a display device according to one or more other embodiments.

Referring to FIG. 1, a display device 10 is a device for displaying video and/or still images, such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PCs (UMPC), as well as display screens for a variety of products such as televisions, laptops, monitors, billboards, and/or the internet of things (IoT).

The display device 10 may be a light-emitting display device, such as an organic light-emitting display device utilizing an organic light-emitting diode (OLED), a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description focuses on the fact that the display device 10 is a micro-light-emitting display device, but the present disclosure is not limited thereto. On the other hand, a micro light-emitting diode referred to as a light-emitting element in the following for convenience of explanation.

The display device 10 includes a display panel 100, a display driving circuit 250, a circuit board 300, and a power supply circuit 500.

The display panel 100 may be formed as a rectangular-shaped plane having a short side in the first direction DR1 and a long side in the second direction DR2 that intersects the first direction DR1. A corner where the short side in the first direction DR1 and the long side in the second direction DR2 meet may be rounded to have a suitable curvature (e.g., a predetermined curvature) or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be formed to be flexible, such as to be able to be bent, curved, bent, folded, and/or rolled.

The substrate SUB of the display panel 100 may include a main area MA and a sub-area SBA.

The main area MA may include a display area DA that displays an image and a non-display area NDA that is a peripheral area of the display area DA and is around the display area DA along an edge or a periphery of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be located on the bottom surface of the display panel 100. When the sub-area SBA is bent, it may overlap the main area MA in the third direction DR3, which is the thickness direction of the display panel 100. The display driving circuit 250 may be located in the sub-area SBA.

The display driving circuit 250 may generate signals and voltages for driving the display panel 100. The display driving circuit 250 may be formed as an integrated circuit (IC) and attached to the display panel 100 using a chip-on-glass (COG) method, a chip-on-plastic (COP) method, or an ultrasonic bonding method but is not limited thereto. For example, the display driving circuit 250 may be attached to the circuit board 300 using a chip on film (COF) method.

The circuit board 300 may be attached to one end of the sub-area SBA of the display panel 100. As such, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible film, such as a flexible printed circuit board (FPCB), a printed circuit board (PCB), or a chip on film (COF).

The power supply circuit 500 may generate a plurality of panel-driving voltages according to an external power supply voltage. The power supply circuit 500 may be formed as an integrated circuit (IC) and attached to the circuit board 300 using a COF method.

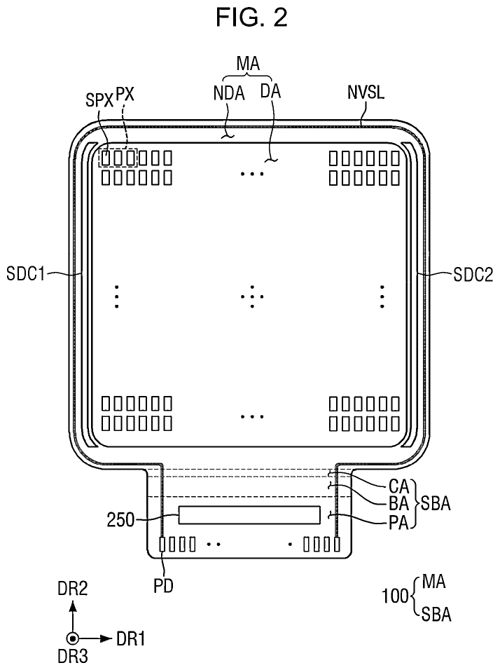

FIG. 2 is a layout diagram illustrating a display device according to one or more embodiments. FIG. 2 illustrates that the sub-area SBA is unfolded without being bent.

Referring to FIG. 2, the display panel 100 may include the main area MA and the sub-area SBA.

The main area MA may include the display area DA that displays an image and the non-display area NDA that is a peripheral area of the display area DA. The display area DA may occupy most of the main area MA. The display area DA may be placed in the center of the main area MA.

The display area DA may include a plurality of pixels PX for displaying an image, and each of the plurality of pixels PX may include a plurality of sub-pixels SPX. A pixel PX may be defined as a sub-pixel group of the smallest unit capable of expressing a white grayscale.

The non-display area NDA may be placed adjacent to the display area DA. The non-display area NDA may be an area outside the display area DA. The non-display area NDA may be arranged to be around (e.g., to surround) the display area DA. The non-display area NDA may be an edge area of the display panel 100.

A first scan driver SDC1 and a second scan driver SDC2 may be located in the non-display area NDA. The first scan driver SDC1 is located on one side (for example, the left side) of the display panel 100, and the second scan driver SDC2 is located on the other side (for example, the right side) of the display panel 100. However, it is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive a scan control signal from the display driving circuit 250, generate scan signals according to the scan control signal, and output them to the scan lines.

The sub-area SBA may protrude from one side of the main area MA in the second direction DR2. The length of the sub-area SBA in the second direction DR2 may be smaller than the length of the main area MA in the second direction DR2. The length in the first direction DR1 of the sub-area SBA is smaller than the length in the first direction DR1 of the main area MA or may be substantially equal to the length in the first direction DR1 of the main area MA. The sub-area SBA may be curved and may be located at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may be in contact with the non-display area NDA of the main area MA, and the other side of the connection area CA may be in contact with the bending area BA.

The pad area PA is an area where the pads PD and the display driving circuit 250 are located. The display driving circuit 250 may be attached to the driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is a bent area. When the bending area BA is bent, the pad area PA may be located below the connection area CA and below the main area MA (e.g., in a thickness direction). The bending area BA may be located between the connection area CA and the pad area PA. One side of the bending area BA may be in contact with the connection area CA, and the other side of the bending area BA may be in contact with the pad area PA.

A non-display power supply line NVSL may be disposed in the non-display area NDA, the connection area CA, the bending area BA, and the pad area PA.

The non-display power supply line NVSL may be disposed on four sides of the display area DA in the non-display area NDA. The non-display power supply line NVSL may be arranged to be around (e.g., to surround) at least three sides of the display area DA. For example, the non-display power supply line NVSL may be around (e.g., to surround) the left, top, and right sides of the display area DA and may be disposed on at least a portion of the lower side. Further, the non-display power supply line NVSL may be disposed outside the first scan driving portion SDC1 and outside the second scan driving portion SDC2. For example, the non-display power supply line NVSL may be disposed on the left side of the first scan driving portion SDC1 and on the right side of the second scan driving portion SDC2. Alternatively, the non-display power supply line NVSL may overlap the first scan driving portion SDC1 and the second scan driving portion SDC2.

The non-display power supply line NVSL may be disposed at the left and right edges of the connection area CA and the bending area BA. The non-display power supply line NVSL may be connected to a pad PD adjacent to one side edge and a pad PD adjacent to the other side edge from among the pads PD in the pad area PA.

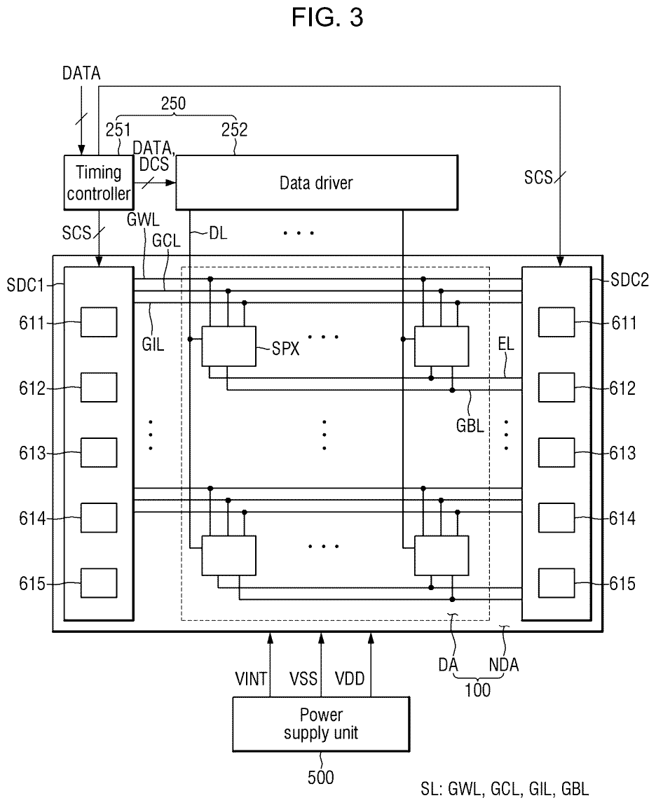

FIG. 3 is a block diagram illustrating a display device according to one or more embodiments.

Referring to FIG. 3, the display area DA includes a plurality of pixels PX, a plurality of scan lines SL, a plurality of emission control lines EL, and a plurality of data lines DL. Each of the plurality of pixels includes a plurality of sub-pixels SPX.

The plurality of pixels PX may be arranged in a matrix form in the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1 and be arranged along the second direction DR2. The plurality of data lines DL may extend in the second direction DR2 and be arranged along the first direction DR1. The plurality of scan lines SL may include a plurality of write scan lines GWL, a plurality of control scan lines GCL, a plurality of initialization scan lines GIL, and a plurality of bias scan lines GBL.

Each of the plurality of sub-pixels SPX may be connected to a write scan line GWL from among the plurality of write scan lines GWL, a control scan line GCL from among the plurality of control scan lines GCL, an initialization scan line GIL from among the plurality of initialization scan lines GIL, a bias scan line GBL from among the plurality of bias scan lines GBL, an emission control line EL from among the plurality of emission control lines EL, and a data line DL from among the plurality of data lines DL. Each of the plurality of sub-pixels SPX may be supplied with a data voltage of the data line DL according to the write scan signal of the write scan line GWL and may emit light from the light-emitting elements according to the data voltage.

The non-display area NDA includes a first scan driver SDC1, a second scan driver SDC2, and a display driving circuit 250.

Each of the first scan driver SDC1 and the second scan driver SDC2 may include a write scan signal output unit 611, a control scan signal output unit 612, an initialization scan signal output unit 613, a bias scan signal output unit 614, and a light-emitting signal output unit 615. Each of the write scan signal output unit 611, the control scan signal output unit 612, the initialization scan signal output unit 613, the bias scan signal output unit 614, and the light-emitting signal output unit 615 may receive a scan-timing control signal SCS from the timing control circuit 400. The write scan signal output unit 611 may generate write scan signals according to the scan-timing control signal SCS of the timing control circuit 400 and sequentially output them to the write scan lines GWL. The control scan signal output unit 612 may generate control scan signals according to the scan-timing control signal SCS and sequentially output them to the control scan lines GCL. The initialization scan signal output unit 613 may generate initialization scan signals according to the scan-timing control signal SCS and sequentially output them to the initialization scan lines GIL. The bias scan signal output unit 614 may generate bias scan signals according to the scan-timing control signal SCS and sequentially output them to the bias scan lines EBL. The light-emitting signal output unit 615 may generate light-emitting control signals according to the scan-timing control signal SCS and sequentially output them to the emission control lines EL.

The display driving circuit 250 includes a timing control circuit 251 and a data-driving circuit 252.

The data-driving circuit 252 may receive digital video data DATA and a data-timing control signal DCS from the timing control circuit 251. The data-driving circuit 252 converts digital video data DATA into analog data voltages according to the data-timing control signal DCS and outputs them to the data lines DL. In this case, the sub-pixels SPX are selected by the write scan signals of the first scan driver SDC1 and the second scan driver SDC2, and data voltages may be supplied to the selected sub-pixels SPX.

The timing control circuit 251 may receive digital video data and timing signals from an external source. The timing control circuit 251 may generate the scan-timing control signal SCS and the data-timing control signal DCS to control the display panel 100 according to timing signals. The timing control circuit 400 may output the scan-timing control signal SCS to the first scan driver SDC1 and the second scan-driving unit SDC2. The timing control circuit 251 may output digital video data DATA and a data-timing control signal DCS to the data-driving circuit 252.

The power supply circuit 500 may generate a plurality of panel-driving voltages according to an external power supply voltage. For example, the power supply circuit 500 may generate and may supply a first driving voltage VDD, a second driving voltage VSS, and a third driving voltage VINT to the display panel 100.

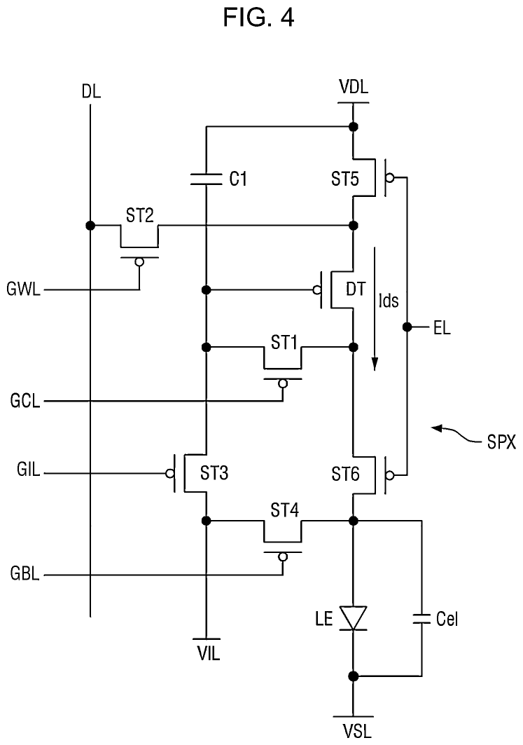

FIG. 4 is an equivalent circuit diagram illustrating a sub-pixel according to one or more embodiments.

Referring to FIG. 4, the sub-pixel SPX according to one or more embodiments may be connected to scan lines GWL, GIL, GCL, and GBL, an emission line EL, and a data line DL. For example, the sub-pixel SPX may be connected to the write scan line GWL, the initialization scan line GIL, the control scan line GCL, the bias scan line GBL, the emission line EL, and the data line DL.

The sub-pixel SPX according to one or more embodiments includes a driving transistor DT, switch elements, a capacitor C1, and a light-emitting element LE. The switch elements include first to sixth transistors ST1, ST2, ST3, ST4, ST5, and ST6.

The driving transistor DT includes a gate electrode, a first electrode, and a second electrode. The driving transistor DT controls the drain-source current (Ids, hereinafter referred to as “driving current”) flowing between the first electrode and the second electrode according to the data voltage applied to the gate electrode.

The light-emitting element LE may be a micro light-emitting diode.

The light-emitting element LE emits light according to the driving current Ids. The amount of light emitted from the light-emitting element LE may be proportional to the driving current Ids. The anode electrode of the light-emitting element LE may be connected to the first electrode of the fourth transistor ST4 and the second electrode of the sixth transistor ST6, and the cathode electrode may be connected to the second power supply line VSL to which the second power voltage is applied. A parasitic capacitance Cel may be formed between the anode electrode and the cathode electrode of the light-emitting element LE.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as P-type metal oxide semiconductor field effect transistor (MOSFET). In this case, the active layer of each of the first to sixth transistors ST1, ST2, ST3, ST4, ST5, and ST6 and the driving transistor DT may be formed of polysilicon.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. The gate electrodes of the fifth and sixth transistor ST5 and ST6 may be connected to the emission line EL. Because the first to sixth transistors ST1, ST2, ST3, ST4, ST5, and ST6 are formed as P-type MOSFET, they may be turned on when a scan signal of the gate low voltage and an emission signal of a low voltage are applied to the control scan line GCL, the initialization scan line GIL, the write scan line GWL, the bias scan line GBL, and the emission line EL, respectively. One electrode of the third transistor ST3 and one electrode of the fourth transistor ST4 may be connected to an initialization voltage line VIL.

For example, the first transistor ST1 may be connected between the second electrode and the gate electrode of the driving transistor DT. The second transistor ST2 may be connected between the data line DL and the first electrode of the driving transistor DT. The third transistor ST3 may be connected between the initialization voltage line VIL and the gate electrode of the driving transistor DT. The fourth transistor ST4 may be connected between the initialization voltage line VIL and the light-emitting element LE. The fifth transistor ST5 may be connected between the first power supply line VDL and the first electrode of the driving transistor DT. The sixth transistor ST6 may be connected between the second electrode of the driving transistor DT and the light-emitting element LE.

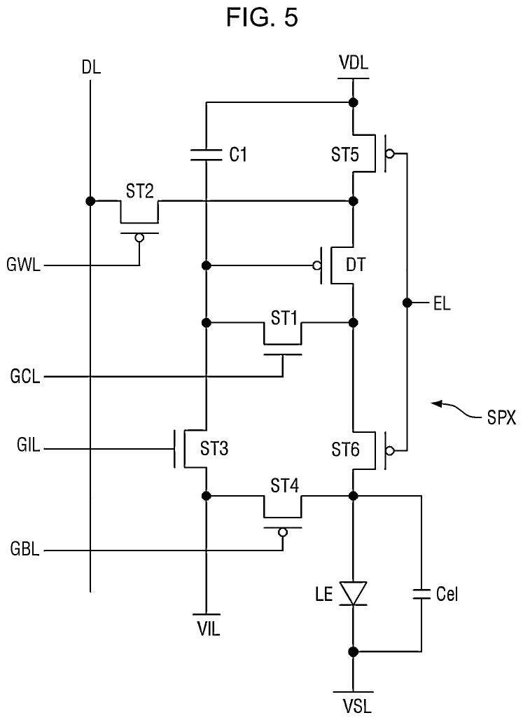

FIG. 5 is an equivalent circuit diagram illustrating a sub-pixel according to one or more embodiments.

Referring to FIG. 5, the driving transistor DT, the second transistor ST2, the fourth transistor ST4, the fifth transistor ST5, and the sixth transistor ST6 are formed of P-type MOSFET, and the first transistor ST1 and the third transistor ST3 may be formed as N-type MOSFET. The active layer of each of the driving transistor DT, the second transistor ST2, the fourth transistor ST4, the fifth transistor ST5, and the sixth transistor ST6 formed as the P-type MOSFET may be formed of polysilicon, and the active layer of each of the first transistor ST1 and the third transistor ST3 formed as the N-type MOSFET may be formed of the oxide semiconductor. In this case, transistors formed of polysilicon and transistors formed of oxide semiconductors may be arranged in different layers.

Because the first transistor ST1 and the third transistor ST3 are formed as N-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as P-type MOSFET, so they may be turned on when a scan signal with a gate low voltage and an emission signal with a low voltage are applied to the write scan line GWL, the bias scan line GBL, and the emission line EL, respectively.

Alternatively, the fourth transistor ST4 in FIG. 4 may be formed of the N-type MOSFET. In this case, the active layer of each fourth transistor ST4 may be formed of the oxide semiconductor. When the fourth transistor ST4 is formed of n-type MOSFET, it may be turned on when a bias scan signal of a gate high voltage is applied to the bias scan line GBL.

In one or more embodiments, the first to sixth transistors ST1, ST2, ST3, ST4, ST5, and ST6 and the driving transistor DT may all be formed as N-type MOSFET. In this case, the active layer of each of the first to sixth transistors ST1, ST2, ST3, ST4, ST5, and ST6 and the driving transistor DT may be formed of an oxide semiconductor.

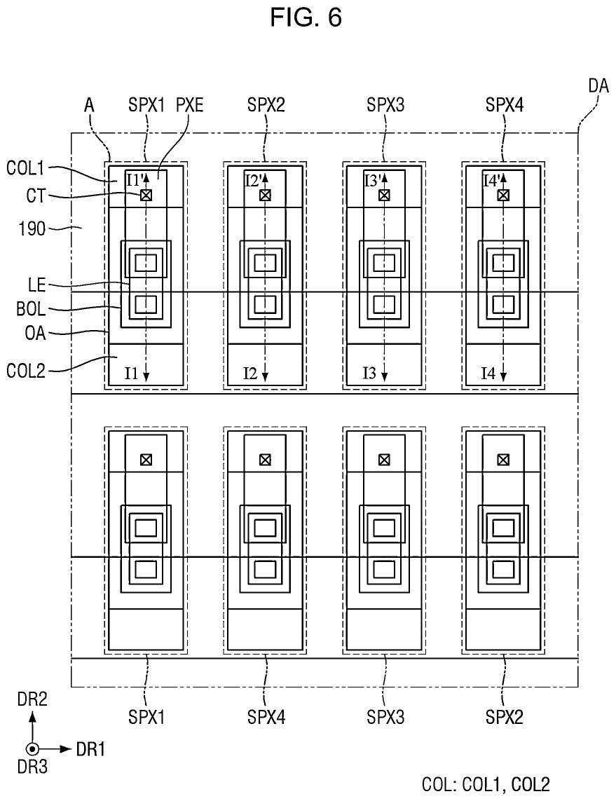

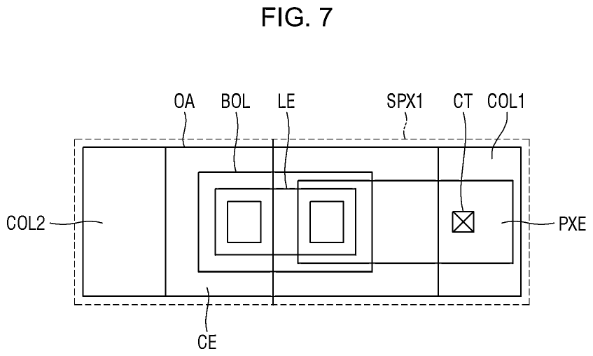

FIG. 6 is a layout diagram illustrating a plurality of pixels in a display area according to one or more embodiments. FIG. 7 is a layout diagram illustrating one example of an area A of FIG. 6 in detail.

Referring to FIGS. 6 and 7, each of the plurality of pixels PX in the display area DA may include a first sub-pixel SPX1, a second sub-pixel SPX2, a third sub-pixel SPX3, and a fourth sub-pixel SPX4.

The plurality of pixels PX may be arranged in a matrix form. Each of the plurality of pixels PX located in the N (N is a positive integer) rows may be arranged along the first direction DR1 in the order of the first sub-pixel SPX1, the second sub-pixel SPX2, the third sub-pixel SPX3, and the fourth sub-pixel SPX4. In each of the plurality of pixels PX arranged in the N+1 row, may be arranged along the first direction DR1 in the following order the first sub-pixel SPX1, the fourth sub-pixel SPX4, the third sub-pixel SPX3, and the second sub-pixel SPX2.

The first sub-pixel SPX1 and the third sub-pixel SPX3 may emit a first light, the second sub-pixel SPX2 may emit a second light, and the fourth sub-pixel SPX4 may emit a third light. Here, the first light may be light in a green wavelength band, the second light may be light in a red wavelength band, and the third light may be light in a blue wavelength band. For example, the blue wavelength band may indicate that the main peak wavelength of the light is included in a wavelength band from approximately 370 μm to approximately 460 μm, the green wavelength band may indicate that the main peak wavelength of the light is included in a wavelength band from approximately 480 μm to approximately 560 μm, and the red wavelength band may indicate that the main peak wavelength of the light is included in a wavelength band from approximately 600 μm to approximately 750 μm. When the first sub-pixel SPX1 and the third sub-pixel SPX3 emit light of the first color, it has the advantage of compensating for light with lower luminous efficiency.

In the above example, the first sub-pixel SPX1 and the third sub-pixel SPX3 emit the same light, but the present disclosure is not limited thereto. For example, the first sub-pixel SPX1 may emit the first light, the second sub-pixel SPX2 may emit the second light, the third sub-pixel SPX3 may emit the third light, and the fourth sub-pixel SPX4 may emit the fourth light. In this case, the fourth light may be light in a monochromatic wavelength band different from the first to third lights or a white light that is a mixture of the first to third light.

However, the arrangement and number of sub-pixels of each of the plurality of pixels PX and the emission wavelength band of the sub-pixels according to the embodiments of the present disclosure are not limited to those described above. For example, each of the plurality of pixels PX may include three sub-pixels arranged in a stripe shape. In this case, each of the plurality of pixels PX may include a first sub-pixel emitting the second light, a second sub-pixel emitting the first light, and a third sub-pixel emitting the third light. In each of the plurality of pixels PX, the first sub-pixel, the second sub-pixel, and the third sub-pixel may be sequentially arranged along the first direction DR1.

Each of the first to fourth sub-pixels SPX1 to SPX4 may include a bank 190 having an opening OA, a pixel electrode PXE, a common electrode CE, a light-emitting element LE, an organic pattern layer BOL, and a conductive layer COL.

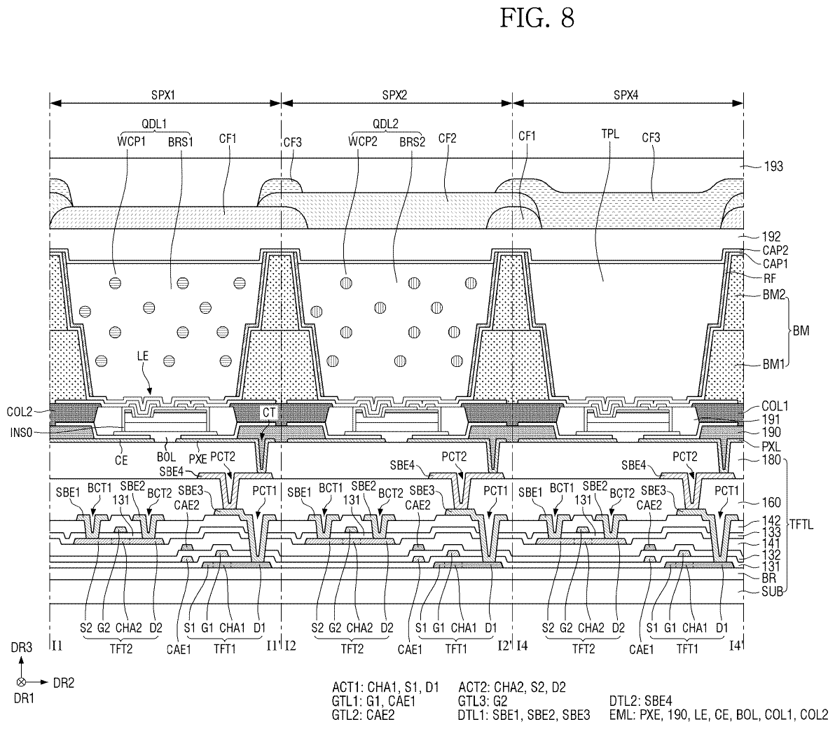

The opening OA is an area partitioned by the bank (190 in FIG. 8) and may be defined as an area where the light-emitting element LE is located in each of the first to fourth sub-pixels SPX1 to SPX4.

The pixel electrode PXE and the common electrode CE are spaced from each other. A portion of the pixel electrode PXE may be located in the first portion of the opening OA, and the remaining portion may be located in an area other than the opening OA. A portion of the common electrode CE may be located in the second portion of the opening OA, and the remaining portion may be located in an area other than the opening OA. At least a portion of the pixel electrode PXE and the common electrode CE may overlap the light-emitting element LE in the thickness direction but is not limited to this. The pixel electrode PXE and the common electrode CE may comprise an opaque metal material.

The organic pattern layer BOL may overlap the pixel electrode PXE and the common electrode CE in the opening OA. The organic pattern layer BOL serves to temporarily fix or adhere the light-emitting element LE during the process of transferring the light-emitting element LE to the display panel 100. That is, the organic pattern layer BOL may be a film for temporarily adhering the light-emitting element LE to the pixel electrode PXE and the common electrode CE in the opening OA.

The light-emitting element LE may have a rectangular planar shape. The light-emitting element LE includes a first contact electrode CTE1 located on one side and a second contact electrode CTE2 located on the other side. The first contact electrode CTE1 and the second contact electrode CTE2 may be spaced from each other in the second direction DR2.

The light-emitting element LE may completely overlap the organic pattern layer BOL. A first portion of the light-emitting element LE may overlap the pixel electrode PXE, and a second portion of the light-emitting element LE may overlap the common electrode CE.

The conductive layer COL may be formed by filling a first conductive wall COL1 and a second conductive wall COL2 with a conductive material in an area compartmentalized in the third organic layer (191 in FIG. 8).

The conductive layer COL overlaps the bank 190 and does not overlap the light-emitting element LE.

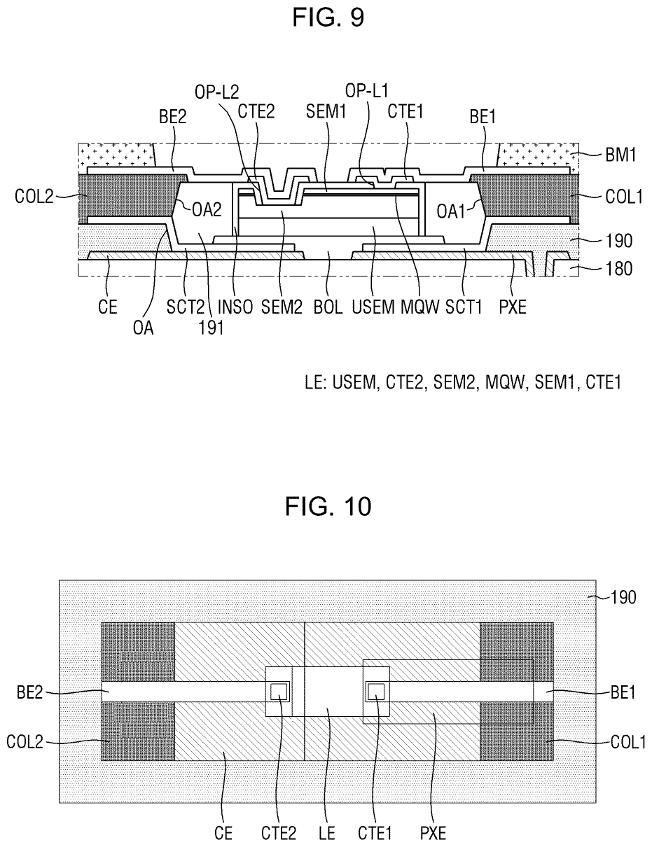

The first conductive wall COL1 serves to electrically connect the first contact electrode CTE1 of the light-emitting element LE and the pixel electrode PXE through a first connection electrode BE1 (e.g., see FIG. 9).

The second conductive wall COL2 serves to electrically connect the second contact electrode CTE2 of the light-emitting element LE and the common electrode CE through a second connection electrode BE2 (e.g., see FIG. 9).

In one or more embodiments, the first conductive wall COL1 may partially overlap at least the first side of the light-emitting element LE. In one or more embodiments, the first side of the light-emitting element LE may completely overlap the first conductive wall COL1. For example, a length of the first conductive wall COL1 in the first direction DR1 may be longer than a length of the light-emitting element LE in the first direction DR1.

In one or more embodiments, the second conductive wall COL2 may partially overlap at least the second side of the light-emitting element LE. In one or more embodiments, the second side of the light-emitting element LE may completely overlap the second conductive wall COL2. For example, the length of the second conductive wall COL2 in the first direction DR1 may be longer than the length of the light-emitting element LE in the first direction DR1. Here, the first side and the second side may be sides facing each other.

One end of the common electrode CE may be connected to a second power supply line (VSL in FIGS. 4 and 5). Each of the second power supply lines VSL may be electrically connected to the non-display power supply line NVSL located in the non-display area NDA as shown in FIG. 2.

A connection hole CT may be an area where the pixel electrode PXE is connected to the fourth source connection electrode (SBE4 in FIG. 8), which is electrically connected to a first source area S1 or a first drain area D1 of the first thin film transistor (TFT1 in FIG. 8). The connection holes CT may overlap with the pixel electrodes PXE.

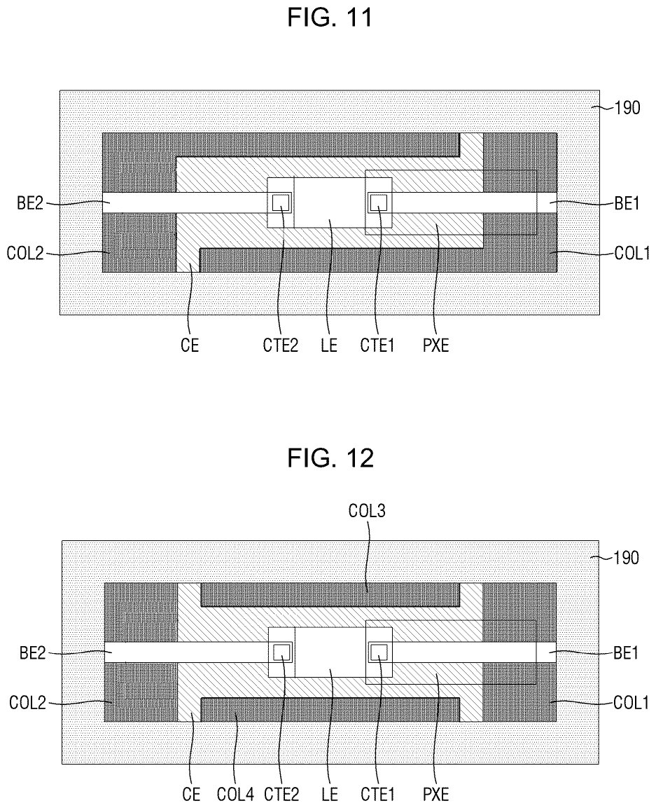

FIG. 8 is a cross-sectional view illustrating an example of a cross-section of a display panel corresponding to the lines 11-11′, 12-12′, and 14-14′ of FIG. 6. FIG. 9 is an enlarged view of the connection structure of the light-emitting element LE of the first sub-pixel SPX1 of FIG. 8. FIG. 10 is a plan view illustrating the light-emitting element, conductive wall, pixel electrode, common electrode, and connection electrode of FIG. 9. FIG. 11 is one or more other embodiments of FIG. 10, and FIG. 12 is one or more other embodiments of FIG. 10.

Referring to FIGS. 8-10, a substrate SUB may be made of an insulating material such as glass, polymer resin, and/or the like. If the substrate SUB is made of polymer resin, it may be a flexible substrate that may be stretched. The polymer resin may be acryl resin, epoxy resin, phenolic resin, polyamide resin, and/or polyimide resin.

A barrier film BR may be disposed on the substrate SUB. The barrier film BR is a membrane for protecting the transistors of a thin film transistor layer TFTL and a light-emitting element layer EML from moisture penetrating through the substrate SUB, which is vulnerable to moisture penetration. The barrier film BR may be composed of a plurality of inorganic films stacked alternately. For example, the barrier film BR may be formed as a multilayer of alternating inorganic films of one or more of a silicon nitride layer, a silicon oxynitride layer, a silicon oxide layer, a titanium oxide layer, and/or an aluminum oxide layer.

A first thin film transistor TFT1 may be disposed on the barrier film BR. The first thin film transistor TFT1 may be either the fourth transistor ST4 or the sixth transistor ST6 shown in FIG. 4. The first thin film transistor TFT1 may include a first active layer ACT1 and a first gate electrode G1.

The first active layer ACT1 of the first thin film transistor TFT1 may be disposed on the barrier film BR. The first active layer ACT1 of the first thin film transistor TFT1 may include polycrystalline silicon, single crystalline silicon, low-temperature polycrystalline silicon, and/or amorphous silicon.

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be located on one side of the first channel area CHA1, and the first drain area D1 may be located on the other side of the first channel area CHA1. The first source area S1 and the first drain area D1 may be areas that do not overlap with the first gate electrode G1 in the third direction DR3. The first source area S1 and the first drain area D1 may be areas in which the silicon semiconductor is doped with ions to make it conductive.

A first gate-insulating film 131 may be located on the first channel area CHA1, the first source area S1, and the first drain area D1 of the first thin film transistor TFT1 and the barrier film BR. The first gate-insulating film 131 may be formed of an inorganic film, for example, a silicon nitride layer, a silicon oxynitride layer, a silicon oxide layer, a titanium oxide layer, and/or an aluminum oxide layer.

A first gate metal layer GTL1 may be located on the first gate-insulating film 131. The first gate metal layer GTL1 may include the first gate electrode G1 of the first thin film transistor TFT1 and a first capacitor electrode CAE1. The first gate electrode G1 may overlap the first active layer ACT1 in the third direction DR3. In FIG. 7, the first gate electrode G1 and the first capacitor electrode CAE1 are shown to be spaced from each other, but the first gate electrode G1 and the first capacitor electrode CAE1 may be connected to each other. The first gate metal layer GTL1 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

A second gate-insulating film 132 may be located on the first gate electrode G1 of the first thin film transistor TFT1, the first capacitor electrode CAE1, and the first gate-insulating film 131. The second gate-insulating film 132 may be formed of an inorganic film, for example, a silicon nitride layer, a silicon oxynitride layer, a silicon oxide layer, a titanium oxide layer, and/or an aluminum oxide layer.

A second gate metal layer GTL2 may be located on the second gate-insulating film 132. The second gate metal layer GTL2 may include a second capacitor electrode CAE2. The second capacitor electrode CAE2 may overlap the first capacitor electrode CAE1 in the third direction DR3. Because the second gate-insulating film 132 has a suitable permittivity (e.g., a predetermined permittivity), a capacitor (C1 in FIG. 5) may be formed by the first capacitor electrode CAE1, the second capacitor electrode CAE2, and the second gate-insulating film 132 located between them. The second gate metal layer GTL2 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

A first interlayer insulating film 141 may be located on the second capacitor electrode CAE2 and the second gate-insulating film 132. The first interlayer insulating film 141 may be formed of an inorganic film, such as a silicon nitride layer, a silicon oxynitride layer, a silicon oxide layer, a titanium oxide layer, and/or an aluminum oxide layer.

A second thin film transistor TFT2 may be located on the first interlayer insulating film 141. The second thin film transistor TFT2 may be either the first transistor ST1 or the third transistor ST3 shown in FIG. 5. The second thin film transistor TFT2 may include a second active layer ACT2 and a second gate electrode G2.

The second active layer ACT2 of the second thin film transistor TFT2 may be located on the first interlayer insulating film 141. The second active layer ACT2 may include an oxide semiconductor. For example, the second active layer ACT2 may include IGZO (indium (In), gallium (Ga), zinc (Zn) and oxygen (O)), IGZTO (indium (In), gallium (Ga), zinc (Zn), tin (Sn) and oxygen (O)), and/or IGTO (indium (In), gallium (Ga), tin (Sn), and/or oxygen (O)).

The second active layer ACT2 may include a second channel area CHA2, a second source area S2, and a second drain area D2. The second channel area CHA2 may be an area that overlaps the second gate electrode G2 in the third direction DR3. The second source area S2 may be located on one side of the second channel area CHA2, and the second drain area D2 may be located on the other side of the second channel area CHA2. The second source area S2 and the second drain area D2 may be areas that do not overlap the second gate electrode G2 in the third direction DR3. The second source area S2 and the second drain area D2 may be areas in which the oxide semiconductor is doped with ions to make it conductive.

A third gate-insulating film 133 may be located on the second active layer ACT2 of the second thin film transistor TFT2 and the first interlayer insulating film 141. The third gate-insulating film 133 may be formed of an inorganic film, for example, a silicon nitride layer, a silicon oxynitride layer, a silicon oxide layer, a titanium oxide layer, and/or an aluminum oxide layer.

A third gate metal layer GTL3 may be located on the third gate-insulating film 133. The third gate metal layer GTL3 may include the second gate electrode G2 of the second thin film transistor TFT2. The second gate electrode G2 may overlap the second active layer ACT2 in the third direction DR3. The third gate metal layer GTL3 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

A second interlayer insulating film 142 may be located on the second gate electrode G2 of the second thin film transistor TFT2 and the third gate-insulating film 133. The second interlayer insulating film 142 may be formed of an inorganic film, for example, a silicon nitride layer, a silicon oxynitride layer, a silicon oxide layer, a titanium oxide layer, and/or an aluminum oxide layer.

A first data metal layer DTL1 may be located on the second interlayer insulating film 142. The first data metal layer DTL1 may include a first source connection electrode SBE3, a second source connection electrode SBE1, and a third source connection electrode SBE2. The first source connection electrode SBE3 may be connected to the first drain area D1 of the first active layer ACT1 through a first source connection hole PCT1 penetrating the first gate-insulating film 131, the second gate-insulating film 132, the first interlayer insulating film 141, the third gate-insulating film 133, and the second interlayer insulating film 142. The second source connection electrode SBE1 may be connected to the second source area S2 of the second active layer ACT2 through a second source connection hole BCT1 penetrating the second interlayer insulating film 142 and the third gate-insulating film 133. The third source connection electrode SBE2 may be connected to the second drain area D2 of the second active layer ACT2 through a third source connection hole BCT2 penetrating the second interlayer insulating film 142 and the third gate-insulating film 133. The first data metal layer DTL1 may be formed as a single layer or multiple layers of one of molybdenum (Mo), aluminum (Al), chromium (Cr), gold (Au), titanium (Ti), nickel (Ni), neodymium (Nd), and copper (Cu), and/or an alloy thereof. For example, the first data metal layer DTL1 may include a first layer made of titanium (Ti), a second layer made of aluminum (Al), and/or a third layer made of titanium (Ti).

A first organic layer 160 may flatten the step due to the first thin film transistor TFT1 and the second thin film transistor TFT2 on the first source connection electrode SBE3, the second source connection electrode SBE1, and the third source connection electrode SBE2, and the second interlayer insulating film 142. The first organic layer 160 may be formed from an organic film such as acrylic resin, epoxy resin, phenolic resin, polyamide resin, polyimide resin, and/or the like.

A second data metal layer DTL2 may be located on the first organic layer 160. The second data metal layer DTL2 may include a fourth source connection electrode SBE4 and a second power supply line VSL. The fourth source connection electrode SBE4 may be connected to the first source connection electrode SBE3 through a second pixel connection hole PCT2 penetrating the first organic layer 160. The second data metal layer DTL2 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof. For example, the second data metal layer DTL2 may include a first layer made of titanium (Ti), a second layer made of aluminum (Al), and/or a third layer made of titanium (Ti).

A second organic layer 180 may be located on the fourth source connection electrode SBE4 and the first organic layer 160. The second organic layer 180 may be formed of an organic layer such as acrylic resin, epoxy resin, phenolic resin, polyamide resin, polyimide resin, and/or the like.

A light-emitting element layer EML may be located on the second organic layer 180. The light-emitting element layer EML may include pixel electrodes PXE, a bank 190, light-emitting elements LE, a common electrode CE, an organic pattern layer BOL, a first conductive wall COL1, and a second conductive wall COL2. Additionally, the light-emitting element layer EML may further include a first auxiliary electrode SCT1, a second auxiliary electrode SCT2, a first connection electrode BE1, and a second connection electrode BE2.

The pixel electrode PXE and the common electrode CE may be located on the second organic layer 180. The pixel electrode PXE and the common electrode CE may be spaced from each other.

The pixel electrode layer PXL may include the pixel electrode PXE and the common electrode CE located respectively. The pixel electrode PXE may be referred to as an anode electrode, and the common electrode CE may be referred to as a cathode electrode.

The pixel electrode PXE may be connected to the fourth source connection electrode SBE4 through the connection hole CT penetrating the second organic layer 180. The pixel electrode PXE may be connected to the first source area S1 or the first drain area D1 of the first thin film transistor TFT1 through the first source connection electrode SBE3 and the fourth source connection electrode SBE4. Therefore, the voltage controlled by the first thin film transistor TFT1 may be applied to the pixel electrode PXE.

The common electrode CE may be commonly connected to neighboring sub-pixels. One end of the common electrode CE may be connected to the second power supply line (VSL in FIG. 4 or 5). Therefore, a second driving voltage VSS may be applied to the common electrode CE.

When the pixel electrode layer PXL is made of a highly reflective metal material, light emitted from the active layer MQW of the light-emitting element LE that proceeds in the downward direction of the light-emitting element LE may be reflected from the pixel electrode PXE and the common electrode CE, and may proceed in the upward direction of the light-emitting element LE. Therefore, because light loss from the light-emitting element LE may be reduced, the light efficiency of the light-emitting 1 element LE may be increased. For example, the pixel electrode layer PXL may be formed as a single layer or multiple layers of one of molybdenum (Mo), aluminum (Al), silver (Ag), platinum (Pt), palladium (Pd), chromium (Cr), gold (Au), titanium (Ti), nickel (1), neodymium (Nd), and/or copper (Cu), and/or an alloy thereof. Specifically, the pixel electrode layer PXL may be a three-layer structure of titanium (Ti)/aluminum (Al)/titanium (Ti), a two-layer structure of titanium (Ti)/copper (Cu), and/or a three-layer structure of titanium (Ti)/copper (Cu)/aluminum (Al), but the present disclosure is not limited thereto.

The bank 190 may be located on the second organic layer 180. The bank 190 is not formed on the entire surface of the second organic layer 180 and may include an opening OA to expose at least a portion of the pixel electrode PXE and the common electrode CE. For example, the bank 190 may be formed to cover the edges of the pixel electrode PXE and the common electrode CE. The opening OA may be an area partitioned by the bank 190. The opening OA may be an area where the bank 190 is not located, exposing the pixel electrode PXE, the common electrode CE, and the second organic layer 180.

The bank 190 may be formed of an organic layer, such as an acrylic resin, epoxy resin, phenolic resin, polyamide resin, polyimide resin, and/or the like. The bank 190 may include a light-blocking material to reduce or prevent the likelihood of light from the light-emitting element LE of one sub-pixel proceeding to the neighboring sub-pixel. For example, the bank 190 may include an inorganic black pigment such as carbon black and/or an organic black pigment.

The first auxiliary electrode SCT1 may extend along a side of the bank 190 on the pixel electrode PXE and may be located on a top surface of the bank 190. The second auxiliary electrode SCT2 may be located on the common electrode CE, extend along the side of the bank 190, and may be located on the top surface of the bank 190. The first auxiliary electrode SCT1 and the second auxiliary electrode SCT2 may be spaced from each other.

The first auxiliary electrode SCT1 and the second auxiliary electrode SCT2 may be formed as a single layer or multiple layers of one of molybdenum (Mo), aluminum (Al), silver (Ag), platinum (Pt), palladium (Pd), chromium (Cr), gold (Au), titanium (Ti), nickel (Ni), neodymium (Nd) and copper (Cu), and/or an alloy thereof. The first auxiliary electrode SCT1 and the second auxiliary electrode SCT2 may be made of a highly reflective metal material such as aluminum (Al).

The organic pattern layer BOL may be located on the pixel electrode PXE and the common electrode CE in each of the sub-pixels SPX1, SPX2, SPX3, and SPX4. The organic pattern layer BOL serves to temporarily fix or adhere the light-emitting element LE during the process of transferring the light-emitting element LE to the display panel 100. That is, the organic pattern layer BOL may be a film for temporarily adhering the light-emitting element LE on the pixel electrode PXE and the common electrode CE. Because a larger thickness of the organic pattern layer BOL facilitates Temporary Tack, the height of the opening OA in which the organic pattern layer BOL is received or the thickness of the bank 190 may be about 0.5 μm or more. The height of the opening OA may be greater than the thickness of the organic pattern layer BOL. The thickness of the organic pattern layer BOL may be greater than the thickness of each of the pixel electrodes PXE1, PXE2, and PXE3.

The organic pattern layer BOL may be in contact with the bottom surface of the light-emitting element LE. Further, the organic pattern layer BOL may contact at least a portion of each side of the light-emitting element LE.

The area(width) of the organic pattern layer BOL may be larger than the area(width) of the light-emitting element LE. The area of the organic pattern layer BOL may be larger than the areas of the first connection electrode BE1 and the area of the second connection electrode BE2.

The organic pattern layer BOL may be a photosensitive organic layer such as photoresist. Alternatively, the organic pattern layer BOL may be formed of acryl resin, epoxy resin, phenolic resin, polyamide resin, a polyimide resin, and/or the like.

In addition, when the plurality of light-emitting elements LE are bonded by eutectic bonding, in which the plurality of light-emitting elements LE are bonded by heat and pressure with bonding electrodes located on each of the plurality of pixel electrodes PXE, the bonding electrodes of each of the plurality of light-emitting elements LE and the bonding electrodes of each of the plurality of pixel electrodes PXE must be accurately aligned, so that any misalignment may lead to a failure in which the light-emitting elements LE do not light up. In contrast, in the present disclosure, each of the plurality of light-emitting elements LE need only be located on the organic pattern layer BOL for pseudo-adhesion in the opening OA defined by the bank 190, which has the advantage that accuracy of alignment is not required as when bonding by eutectic bonding.

In addition, in the case of eutectic bonding, heat and pressure are required to bond the bonding electrodes of each of the plurality of light-emitting elements LE and the bonding electrodes of each of the pixel electrodes PXE, but the light-emitting elements LE may be tilted or damaged by the heat and pressure. In contrast, in the present disclosure, heat and pressure are not required, which has the advantage that the light-emitting element LE is not tilted or damaged by heat and pressure. In each of the sub-pixels SPX1, SPX2, SPX3, and SPX4, the light-emitting element LE may be located on the organic pattern layer BOL. The light-emitting element LE is exemplified as a lateral type micro LED in which the first contact electrode CTE1 and the second contact electrode CTE2 are both located on the top surface of the light-emitting element LE, as shown in FIGS. 8 and 9.

Each of the plurality of light-emitting elements LE may be formed of an inorganic material, such as gallium nitride (GaN). Each of the plurality of light-emitting elements LE may have a length in the first direction DR1, a length in the second direction DR2, and a length in the third direction DR3 of tens to hundreds of μm. For example, each of the plurality of light-emitting elements LE may have a length in the first direction DR1, a length in the second direction DR2, and a length in the third direction DR3 of approximately 100 μm or less.

The plurality of light-emitting elements LE may be formed by growing on a semiconductor substrate such as a silicon substrate and/or sapphire substrate. The plurality of light-emitting elements LE may be directly transferred from the semiconductor substrate to the organic pattern layer BOL of the display panel 100. Alternatively, the plurality of light-emitting elements LE may be transferred to the organic pattern of the display panel 100 through an electrostatic method using an electrostatic head or a stamp method using an elastic polymer material such as PDMS or silicon as a transfer substrate.

Each of the plurality of light-emitting elements LE includes a first contact electrode CTE1, a second contact electrode CTE2, a first semiconductor layer SEM1, an active layer MQW, a second semiconductor layer SEM2, and an undoped semiconductor layer USEM.

The undoped semiconductor layer USEM may be located on the organic pattern layer BOL. The undoped semiconductor layer USEM may be formed as a semiconductor layer that is not doped with an N-type dopant or a P-type dopant, that is, an undoped semiconductor layer. For example, the undoped semiconductor layer USEM may be one of InAlGaN, GaN, AlGaN, InGaN, AlN, and/or InN where the dopant is not doped. For example, the undoped semiconductor layer USEM may be GaN that is not doped with a dopant.

The second semiconductor layer SEM2 may be located on the undoped semiconductor layer USEM. The second semiconductor layer SEM2 may be doped with a second conductive dopant, such as Si, Ge, Sn, and/or the like. For example, the second semiconductor layer SEM2 may be n-GaN doped with N-type Si. The thickness of the second semiconductor layer SEM2 may be approximately 500 nm to approximately 1 μm. The second semiconductor layer SEM2 may include a first portion having a first thickness and a second portion having a second thickness greater than the first thickness.

The active layer MQW may be located on the second semiconductor layer SEM2. For example, the active layer MQW may be located on the first portion SEM2_1 of the second semiconductor layer SEM2. The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN and/or AlGaN but is not limited thereto. Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light.

When the active layer MQW includes InGaN, the color of the emitted light may vary depending on the content of indium (In). For example, as the content of indium (In) increases, the wavelength band of light emitted by the active layer may shift to the red wavelength band, and as the content of indium (In) decreases, the wavelength band of light emitted by the active layer may shift to the blue wavelength band. For example, the content of indium (In) in the active layer MQW of the light-emitting element LE that emits the third light (light in the blue wavelength band) may be approximately 10 wt % to approximately 20 wt %.

The first semiconductor layer SEM1 may be located on the active layer MQW. The first semiconductor layer SEM1 may be one of InAlGaN, GaN, AlGaN, InGaN, AlN, and/or InN doped with a P-type dopant such as Mg, Zn, Ca, Se, Ba, and/or the like. For example, the first semiconductor layer SEM1 may be n-GaN doped with p-type Mg.

The first contact electrode CTE1 and the second contact electrode CTE2 are respectively located on the two openings. For example, the first contact electrode CTE1 may be located on the opening exposing the first semiconductor layer SEM1 and may be in contact with the first semiconductor layer SEM1. The second contact electrode CTE2 may be located on the opening exposing the second semiconductor layer SEM2 (e.g., SEM2_2) and may be in contact with the second semiconductor layer SEM2 (e.g., SEM2_2).

An electron-blocking layer may be located between the first semiconductor layer SEM1 and the active layer MQW. The electron-blocking layer may be a layer to suppress or prevent too many electrons from flowing into the active layer MQW. For example, the electron-blocking layer may be AlGaN and/or P-AlGaN doped with P-type Mg. The electron-blocking layer may be omitted.

A superlattice layer may be located between the active layer MQW and the second semiconductor layer SEM2. The superlattice layer may be a layer for relieving stress between the second semiconductor layer SEM2 and the active layer MQW. For example, the superlattice layer may be formed of InGaN and/or GaN. The superlattice layer may be omitted.

In one or more embodiments, the light-emitting element LE may further include a protective film INS0 to protect the outer surface. The protective film INS0 may be located on the side surfaces of the first semiconductor layer SEM1, the side surfaces of the active layer MQW, and the side surfaces of the second semiconductor layer SEM2. The protective film INS0 may be formed of an inorganic film, for example, a silicon nitride layer, a silicon oxynitride layer, a silicon oxide layer, a titanium oxide layer, or an aluminum oxide layer. the protective layer INS0 is on an entire surface of the light-emitting element LE, excluding a bottom of the light-emitting element LE, and defines an opening exposing the first contact electrode CTE1 and the second contact electrode CTE2 on the top surface of the light-emitting element

The third organic layer 191 covers the first auxiliary electrode SCT1, the second auxiliary electrode SCT2, and the bank 190 to planarize the light-emitting element LE and may be formed to a desired height (e.g., a predetermined height). For example, the third organic layer 191 may be formed at a desired height (e.g., a predetermined height) such that at least a portion of the light-emitting element LE, such as the first contact electrode CTE1 and the second contact electrode CTE2, may protrude above the third organic layer 191. That is, the height of the third organic layer 191 may be less than the height of the light-emitting element LE.

The third organic layer 191 may include a first electrode opening OA1 penetrating the third organic layer 191 to expose the first auxiliary electrode SCT1 and a second electrode opening OA2 penetrating the third organic layer 191 to expose the second auxiliary electrode SCT2.

The first electrode opening OA1 may partially overlap at least the first side of the light-emitting element LE. The first side of the light-emitting element LE may completely overlap the first electrode opening OA1. For example, the length of the first electrode opening OA1 in the first direction may be longer than the length of the light-emitting element LE in the first direction.

The second electrode opening OA2 may partially overlap at least the second side of the light-emitting element LE. The second side of the light-emitting element LE may completely overlap the second electrode opening OA2. For example, the length of the second electrode opening OA2 in the first direction may be longer than the length of the light-emitting element LE in the first direction.

Referring to FIGS. 8-10, a first conductive wall COL1 is formed by filling the first electrode opening OA1 with a conductive material. Accordingly, the first conductive wall COL1 may partially overlap at least the first side of the light-emitting element LE. The first side of the light-emitting element LE may completely overlap the first conductive wall COL1. For example, the length of the first conductive wall COL1 in the first direction DR1 may be longer than the length of the light-emitting element LE in the first direction DR1.

The first conductive wall COL1 may be in contact with the first auxiliary electrode SCT1 on the top surface of the bank 190. That is, the first conductive wall COL1 may be electrically connected to the pixel electrode PXE through the first auxiliary electrode SCT1 on the top surface of the bank 190. To this end, the first conductive wall COL1 may be connected to the first auxiliary electrode SCT1 connected to the pixel electrode PXE and the first connection electrode BE1 connected to the first contact electrode CTE1 of the light-emitting element LE. The first conductive wall COL1 may overlap at least a portion of the first auxiliary electrode SCT1 and at least a portion of the first connection electrode BE1.

The second conductive wall COL2 is formed by filling the second electrode opening OA2 with a conductive material. Accordingly, the second conductive wall COL2 may partially overlap at least the second side of the light-emitting element LE. The second side of the light-emitting element LE may completely overlap the second conductive wall COL2. For example, the length of the second conductive wall COL2 in the first direction may be longer than the length of the light-emitting element LE in the first direction.

The second conductive wall COL2 may be in contact with the second auxiliary electrode SCT2 on the top surface of the bank 190. That is, the second conductive wall COL2 may be electrically connected to the common electrode CE through the second auxiliary electrode SCT2 on the top surface of the bank 190. To this end, the second conductive wall COL2 may be connected to the second auxiliary electrode SCT2 connected to the common electrode CE and to the second connection electrode BE2 connected to the second contact electrode CTE2 of the light-emitting element LE. The second conductive wall COL2 may overlap at least a portion of the second auxiliary electrode SCT2 and at least a portion of the second connection electrode BE2.

The area of the pixel electrode PXE may be larger than the area of the first connection electrode BE1. The area of the common electrode CE within the sub-pixel may be larger than the area of the second connection electrode BE2.

The first connection electrode BE1 connects the first contact electrode CTE1 of the light-emitting element LE and the first conductive wall COL1. The first connection electrode BE1 may be located on the top and side surfaces of the first contact electrode CTE1 and on the top surface of the first semiconductor layer SEM1. The first connection electrode BE1 extends from the top and side surfaces of the first contact electrode CTE1 and the top surface of the first semiconductor layer SEM1 to the top surface of the first conductive wall COL1.

The first conductive wall COL1 may be electrically connected to the first contact electrode CTE1 of the light-emitting element LE through the first connection electrode BE1 on the top surface of the bank 190. Accordingly, the first contact electrode CTE1, the first connection electrode BE1, the first conductive wall COL1, the first auxiliary electrode SCT1, and the pixel electrode PXE may be electrically connected.

The second connection electrode BE2 connects the second contact electrode CTE2 of the light-emitting element LE to the second conductive wall COL2. The second connection electrode BE2 may be located on the top surface and one side of the second contact electrode CTE2. The second connection electrode BE2 extends from the top and side surfaces of the second contact electrode CTE2 to the top surface of the second conductive wall COL2. The first connection electrode BE1 and the second connection electrode BE2 comprise a transparent conductive oxide.

The second conductive wall COL2 may be electrically connected to the second contact electrode CTE2 of the light-emitting element LE through the second connection electrode BE2 on the top surface of the bank 190. Accordingly, the second contact electrode CTE2, the second connection electrode BE2, the second conductive wall COL2, the second auxiliary electrode SCT2, and the common electrode CE may be electrically connected.

The first conductive wall COL1 and the second conductive wall COL2 may include a conductive material and may further include a light-blocking material. The light-blocking material may include an inorganic black pigment, such as carbon black and/or an organic black pigment.

In one or more embodiments, the light-blocking material may be omitted. When the first conductive wall COL1 and the second conductive wall COL2 include a light-blocking material, the light emitted from the light-emitting element LE toward the first conductive wall COL1 and the second conductive wall COL2 may be prevented, thereby reducing light mixing between pixels.

The first connection electrode BE1 and the second connection electrode BE2 may include a transparent metal material (TCO), such as indium tin oxide (ITO) and/or indium zinc oxide (IZO), which may transmit light.

FIG. 10 illustrates that the first conductive wall COL1 and the second conductive wall COL2 are arranged to overlap the first and second sides of the light-emitting element LE, but the present disclosure is not limited thereto. For example, as illustrated in FIG. 11, the first conductive wall COL1 overlaps the first side of the light-emitting element LE and the third side adjacent to the first side, and the second conductive wall COL2 may be arranged to overlap the second side of the light-emitting element LE and a fourth side adjacent to the second side. The first side and the second side of the light-emitting element LE are parallel to each other.

Referring to FIG. 11, the first side of the light-emitting element LE and the third side adjacent to the first side completely overlap the first conductive wall COL1. In one or more embodiments, the first conductive wall COL1 partially overlaps the first side of the light-emitting element LE and the third side adjacent to the first side. The third side and the fourth side may be opposite each other. The first side and the third side may be perpendicular to each other, the third side may be in parallel to the fourth side, and the second side and the fourth side may be perpendicular to each other.

The second side of the light-emitting element LE and the fourth side adjacent to the second side completely overlap the second conductive wall COL2. In one or more embodiments, the second conductive wall COL2 partially overlaps the second side of the light-emitting element LE and the fourth side adjacent to the second side.

As shown in FIG. 11, when the first conductive wall COL1 and the second conductive wall COL2 overlap the first to fourth sides of the light-emitting element LE, most of the light emitted from the light-emitting element LE to the side may be blocked, thereby more effectively preventing or reducing mixing with other pixels.

As shown in FIG. 12, the first conductive wall COL1 and the second conductive wall COL2, which overlap the first and second sides of the light-emitting element LE, may be spaced from the third conductive wall COL3 and the fourth conductive wall COL4, which are located on the third and fourth sides of the light-emitting element LE, respectively. In FIG. 12, the third conductive wall COL3 and the fourth conductive wall COL4 are illustrated as being located within the opening OA but are not limited thereto and may be located on the bank 190.

For example, referring back to FIG. 8, a light-blocking layer BM may be located on the bank 190. The light-blocking layer BM may overlap the bank 190 and may not overlap the plurality of light-emitting elements LE.

The light-blocking layer BM may include a first light-blocking layer BM1 and a second light-blocking layer BM2 that are sequentially stacked. A length of the first light-blocking layer BM1 in the first direction DR1 or the length of the second direction DR2 may be greater than a length of the second light-blocking layer BM2 in the first direction DR1 or the length of the second direction DR2. The height of the first light-blocking layer BM1 may be greater than the height of the second light-blocking layer BM2. The first light-blocking layer BM1 and the second light-blocking layer BM2 may be formed of an organic layer such as acrylic resin, epoxy resin, phenolic resin, polyamide resin, polyimide resin, and/or the like. The first light-blocking layer BM1 and the second light-blocking layer BM2 may include a light-blocking material to reduce or prevent light from the light-emitting element LE of one sub-pixel proceeding to the neighboring sub-pixel. For example, the first light-blocking layer BM1 and the second light-blocking layer BM2 may include an inorganic black pigment, such as carbon black or an organic black pigment.

The first light conversion layer QDL1, the second light conversion layer QDL2, and the light transmission layer TPL may be located on the light-emitting element layer EML. The first light conversion layer QDL1, the second light conversion layer QDL2, and the light transmission layer TPL may be located in an area partitioned by the light-blocking layer BM. For example, the first light conversion layer QDL1 may be located on the first capping layer CAP1 in the first sub-pixel SPX1 and the third sub-pixel SPX3, the second light conversion layer QDL2 may be located on the first capping layer CAP1 in the second sub-pixel SPX2, and the light transmission layer TPL may be located on the first capping layer CAP1 in the fourth sub-pixel SPX4.

The first light conversion layer QDL1 may convert a portion of the third light (e.g., light in the blue wavelength band) incident from the light-emitting element LE into first light (e.g., light in the green wavelength band). The first light conversion layer QDL1 may include a first base resin BRS1 and first wavelength conversion particles WCP1. The first base resin BRS1 may include a light transmission organic material. For example, the first base resin BRS1 may include an epoxy-based resin, an acrylic-based resin, a cardo-based resin, and/or an imide-based resin. The first wavelength conversion particle WCP1 may convert a portion of the third light (e.g., light in the blue wavelength band) incident from the light-emitting element LE into first light (e.g., light in the green wavelength band). The first wavelength conversion particle WCP1 may be a quantum dot (QD), a quantum rod, a fluorescent material, and/or a phosphorescent material. The first light conversion layer QDL1 may further include a light diffusion agent such as titanium dioxide (TiO₂).

The second light conversion layer QDL2 may convert a portion of the third light (e.g., light in the blue wavelength band) incident from the light-emitting element LE into second light (e.g., light in the red wavelength band). It may include the second base resin BRS2 and the second wavelength conversion particle WCP2. The second base resin BRS2 may include a light transmission organic material. For example, the second base resin BRS2 may include epoxy resin, acrylic resin, cardo resin, and/or imide resin. The second wavelength conversion particle WCP2 may convert a portion of the third light (e.g., light in the blue wavelength band) incident from the light-emitting element LE into second light (e.g., light in the red wavelength band). The second wavelength conversion particle WCP2 may be a quantum dot (QD), a quantum rod, a fluorescent material, and/or a phosphorescent material. The second light conversion layer (QDL2) may further include a light diffusion agent such as titanium dioxide (TiO₂).

The light transmission layer TPL may include a light transmission organic material. For example, the light transmission layer TPL may include epoxy resin, acrylic resin, cardo resin, and/or imide resin.

In one or more embodiments of the present disclosure, a third light conversion layer may be located instead of the light transmission layer TPL. In this case, the third light conversion layer may include a material different from the first light conversion layer QDL1 and the second light conversion layer QDL2. For example, the first light conversion layer QDL1 may include quantum dots that convert light in the blue wavelength band into light in the green wavelength band, the second light conversion layer QDL2 may include quantum dots that convert light in the blue wavelength band to light in the red wavelength band, and the third light conversion layer may include a blue phosphor. In addition, each of the first light conversion layer QDL1, the second light conversion layer QDL2, and the third light conversion layer may include quantum dots and a light diffusion agent such as titanium dioxide (TiO₂). In this case, the number of titanium dioxide (TiO₂) particles in the third light conversion layer may be greater than the number of titanium dioxide (TiO₂) particles in the first light conversion layer QDL1 or the number of titanium dioxide (TiO₂) particles in the second light conversion layer QDL2.

The first capping layer CAP1 may be located between the light-emitting element layer EML and the first wavelength conversion layer QDL1, between the light-emitting element layer EML and the second wavelength conversion layer QDL2, between the light-emitting layer EML and the light transmission layer TPL, between the light-blocking layer BM and the first wavelength conversion layer QDL1, between the light-blocking layer BM and the second wavelength conversion layer QDL2, or between the light-blocking layer BM and the light transmission layer TPL. The first capping layer CAP1 may be formed of an inorganic film, for example, a silicon nitride layer, a silicon oxynitride layer, a silicon oxide layer, a titanium oxide layer, and/or an aluminum oxide layer. The first capping layer CAP1 may be located on the top surface of the light-blocking layer BM.

The reflective layer RF may be located between the light-blocking layer BM and the first light conversion layer QDL1, between the light-blocking layer BM and the second light conversion layer QDL2, and between the light-blocking layer BM and the light transmission layer TPL. The reflective layer RF may be located on the first capping layer CAP1 located on the side of the first light-blocking layer BM1 and the side of the second light-blocking layer BM2. The reflective layer RF serves to reflect light proceeding in the lateral direction from the first light conversion layer QDL1, the second light conversion layer QDL2, and the light transmission layer TPL.

The reflective layer RF may include a highly reflective metal material such as aluminum (Al). The thickness of the reflective layer RF may be approximately 0.1 μm.

Alternatively, the reflective layer RF may include M (M is an integer of 2 or more) pairs of first and second layers having different refractive indices to serve as Distributed Bragg Reflectors (DBR). In this case, M first layers and M second layers may be arranged alternately. The first layer and the second layer may be formed of an inorganic film, for example, a silicon nitride layer, a silicon oxy nitride layer, a silicon oxide layer, a titanium oxide layer, or an aluminum oxide layer.

The second capping layer CAP2 may be located on the first capping layer CAP1, the first light conversion layer QDL1, the second light conversion layer QDL2, and the light transmission layer TPL. The second capping layer CAP2 may be formed of an inorganic film, for example, a silicon nitride layer, a silicon oxy nitride layer, a silicon oxide layer, a titanium oxide layer, and/or an aluminum oxide layer.

Because the first capping layer CAP1 and the second capping layer CAP2 serve to protect the first wavelength conversion particles WCP1 in the first light conversion layer QDL1 and the second wavelength conversion particles WCP2 in the second light conversion layer QDL2 from moisture and/or oxygen, the first light conversion layer QDL1, the second light conversion layer QDL2, and the light transmission layer TPL may be encapsulated by the first capping layer CAP1 and the second capping layer CAP2.

In addition, the first capping layer CAP1 and the second capping layer CAP2 may be formed of a low refractive index material with a lower refractive index than a fourth organic layer 192. In this case, total reflection of light converted in the first light conversion layer QDL1 or the second light conversion layer QDL2 in the first capping layer CAP1 and the second capping layer CAP2 may be prevented or minimized. Therefore, the light converted in the first light conversion layer QDL1 or the second light conversion layer QDL2 may be focused on the top of the first light conversion layer QDL1 or the second light conversion layer QDL2. For example, the refractive index of at least one of the first capping layer CAP1 and the second capping layer CAP2 may be approximately 1.1 to approximately 1.5, and the refractive index of each of the first base resin BRS1 of the first light conversion layer QDL1, the second base resin BRS2 of the second light conversion layer QDL2, and the light transmission layer TPL may be approximately 1.5 to approximately 2.0.

Alternatively, the fourth organic layer 192 may also be formed of a low refractive index material, in which case the light converted by the first light conversion layer QDL1 or the second light conversion layer QDL2 may be prevented, reduced, or minimized from being transmitted by the fourth organic layer 192. Therefore, the light converted in the first light conversion layer QDL1 or the second light conversion layer QDL2 may be focused on the top of the first light conversion layer QDL1 or the second light conversion layer QDL2.

The fourth organic layer 192 may be located on the second capping layer CAP2. The fourth organic layer 192 may be formed of acryl resin, epoxy resin, phenolic resin, polyamide resin, polyimide resin, and/or the like.

When the light-emitting elements LE of the first sub-pixel SPX1, the light-emitting elements LE of the second sub-pixel SPX2, and the light-emitting elements LE of the third sub-pixel SPX3 emit light in the blue wavelength band, the first light conversion layer QDL1 and the second light conversion layer QDL2 are required for wavelength conversion. However, the present disclosure is not limited thereto, and when the light-emitting elements LE of the first sub-pixel SPX1 emit light of the first color, and the light-emitting elements LE of the second sub-pixel SPX2 emit light of the second color, and the light-emitting elements LE of the third sub-pixel SPX3 emit light of the third color, the first light conversion layer QDL1, the second light conversion layer QDL2, and the light transmission layer TPL may be omitted.

Alternatively, when the light-emitting elements LE of the first sub-pixel SPX1 emit light of the first color, and the light-emitting elements LE of the second sub-pixel SPX2 emit light of the second color, and the light-emitting elements LE of the third sub-pixel SPX3 emit light of the third color, phosphor particles may be included instead of wavelength conversion particles to increase color purity.

A plurality of color filters CF1, CF2, and CF3 may be located on the fourth organic layer 192. The plurality of color filters CF1, CF2, and CF3 may include first color filters CF1, second color filters CF2, and third color filters CF3.

The first color filter CF1 located in the first sub-pixel SPX1 and the third sub-pixel SPX3 transmits the first light (e.g., light in the green wavelength band) and absorb or block the third light (e.g., light in the blue wavelength band). Therefore, the first color filter CF1 may transmit the first light (e.g., light in the green wavelength band) converted by the first light conversion layer QDL1 from among the third light (e.g., light in the blue wavelength band) emitted by the light-emitting element LE and absorb and/or block the third light (e.g., light in the blue wavelength band) not converted by the first light conversion layer QDL1. Thus, the first sub-pixel SPX1 may emit the first light (e.g., light in the green wavelength band).

The second color filter CF2 located in the second sub-pixel SPX2 may transmit the second light (e.g., light in the red wavelength band) and absorb or block the third light (e.g., light in the blue wavelength band). Therefore, the second color filter CF2 may transmit the second light (e.g., light in the red wavelength band) converted by the first light conversion layer QDL1 from among the third light (e.g., light in the blue wavelength band) emitted by the light-emitting element LE and absorb and/or block the third light (e.g., light in the blue wavelength band) not converted by the first light conversion layer QDL1. Thus, the second sub-pixel SPX2 may emit the second light (e.g., light in the red wavelength band).

The third color filter CF3 located in the fourth sub-pixel SPX4 may transmit the third light (e.g., light in the blue wavelength band). Therefore, the third color filter CF3 may transmit the third light (e.g., light in the blue wavelength band) emitted by the light-emitting element LE through the light transmission layer TPL. Thus, the fourth sub-pixel SPX4 may emit the third light (e.g., light in the blue wavelength band).

The area where the first color filter CF1, second color filter CF2, and third color filter CF3 overlap may serve as a light-blocking area. The area where the first color filter CF1, second color filter CF2, and third color filter CF3 overlap may overlap with the bank 190 and the light-blocking layer BM.

A fifth organic layer 193 for planarization may be located on the plurality of color filters CF1, CF2, and CF3. The fifth organic layer 193 may be formed of acryl resin, epoxy resin, phenolic resin, polyamide resin, polyimide resin, and/or the like.

Referring to FIGS. 8 and 9, when electrically connecting the light-emitting element LE, the pixel electrode PXE, and the common electrode CE, the connection electrodes BE1 and BE2 are not located in the connection holes that directly expose the pixel electrode PXE and the common electrode CE, but the connection holes are formed with a conductive material. Therefore, the likelihood of disconnection of the connection electrodes BE1 and BE2 may be reduced or prevented, thereby reducing or preventing the light-emitting element LE from emitting light.

In one or more embodiments, the third sub-pixel SPX3 may be formed substantially the same as the first sub-pixel SPX1. Therefore, description of the third sub-pixel SPX3 is omitted.

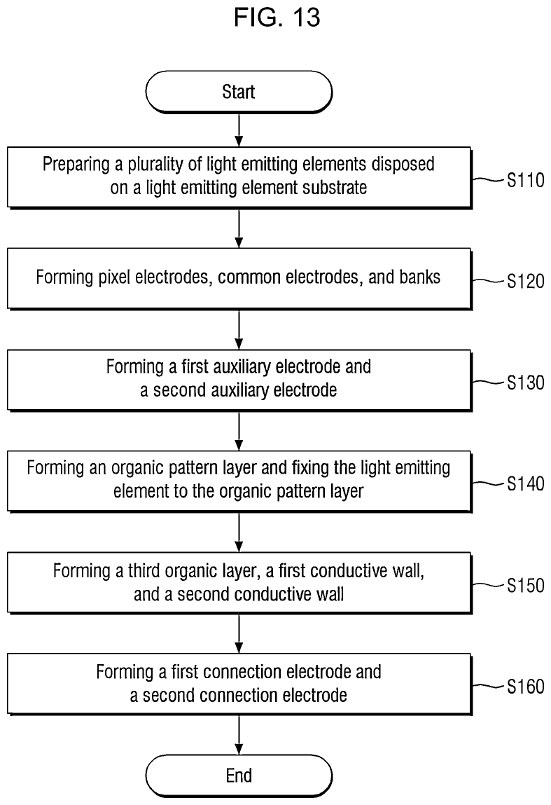

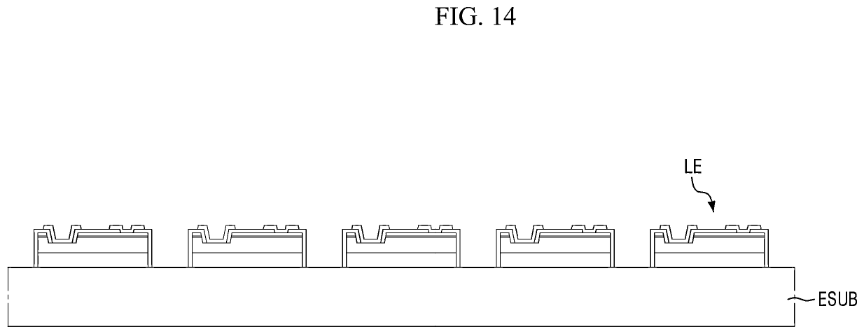

FIG. 13 is a flowchart illustrating a method of manufacturing a display device according to one or more embodiments. FIGS. 14-22 are cross-sectional views to illustrate a method of manufacturing a display device according to one or more embodiments. FIGS. 14-22 show one example of a cross-sectional view of the display device described with reference to FIG. 9.

First, as shown in FIG. 14, a plurality of light-emitting elements LE located on a light-emitting element substrate ESUB are prepared (S110 in FIG. 13).

A plurality of light-emitting elements LE are located on an adhesive layer located on the light-emitting element substrate ESUB. The plurality of light-emitting elements LE are adhered and fixed to the adhesive layer. The light-emitting element substrate ESUB may include a material that allows light to transmit. For example, the light-emitting element substrate ESUB may include a first support layer and an adhesive layer. The first support layer may include a transparent polymer such as polyimide, polyester, polyacrylic, polyepoxy, polyethylene, polystyrene, polyethylene terephthalate, and/or the like. The adhesive layer may include an adhesive material for 1 bonding the plurality of light-emitting elements LE. For example, the adhesive material may include urethane acrylate, epoxy acrylate, polyester acrylate, and/or the like.

A plurality of light-emitting elements LE growing on the semiconductor substrate may be transferred onto the light-emitting element substrate ESUB. The transfer method may use known methods.

Second, a pixel electrode PXE, a common electrode CE, and a bank 190 are formed on the substrate using a mask MSK (S120 in FIG. 13).

Here, the substrate may include a thin film transistor layer TFTL, as described with reference to FIG. 8. A second organic layer 180 may be located on the thin film transistor layer TFTL.

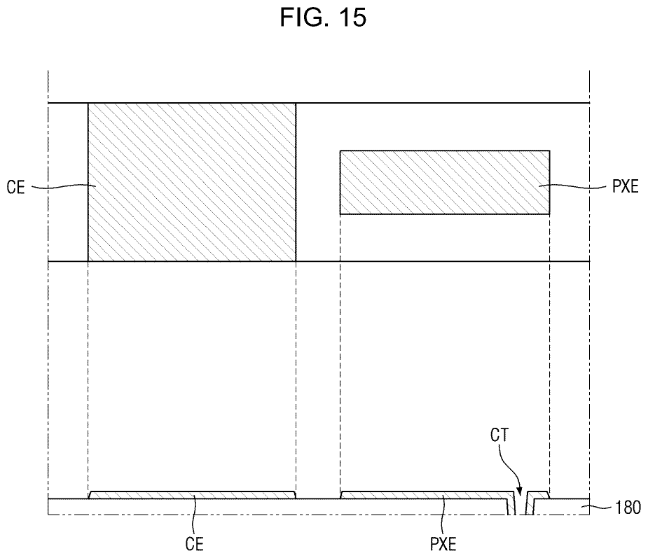

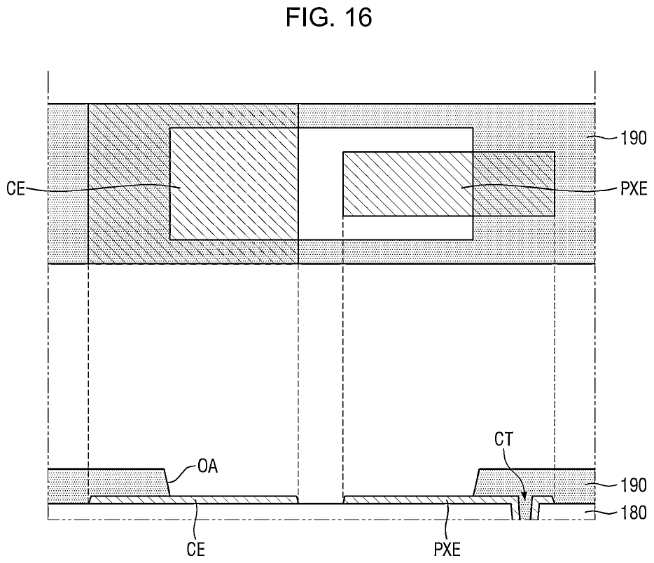

Therefore, referring to FIGS. 15 and 16, the pixel electrodes PXE and the common electrode CE located on the second organic layer 180 are formed using a photolithography process, and then the bank 190 is formed. Each of the pixel electrodes PXE is located in a corresponding connection hole (CT in FIG. 8) and forms common electrodes CE with the pixel electrodes PXE.

Afterwards, a bank 190 having an opening OA exposing at least a portion of the pixel electrodes PXE and the common electrode CE is formed.

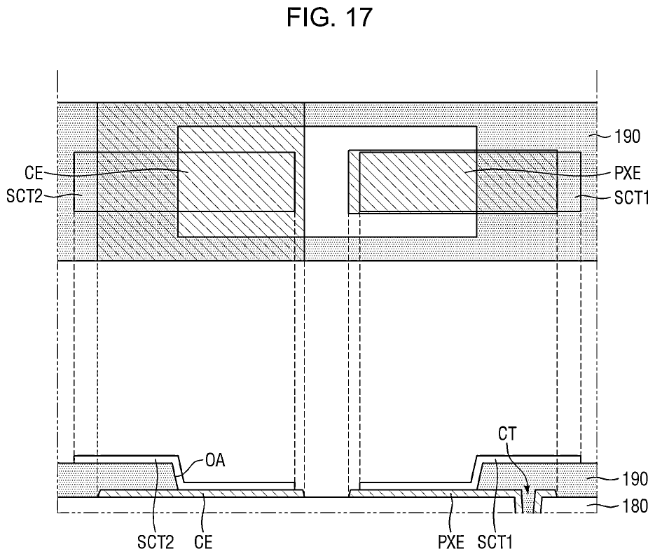

Third, referring to FIG. 17, a first auxiliary electrode SCT1 and a second auxiliary electrode SCT2 are formed using a photolithography process (S130 in FIG. 13).

The first auxiliary electrode SCT1 is formed to extend from the pixel electrode PXE to the top surface of the bank 190. The first auxiliary electrode SCT1 is in direct contact with the pixel electrode PXE.

The second auxiliary electrode SCT2 is formed to extend from the common electrode CE to the top surface of the bank 190. The second auxiliary electrode SCT2 is in direct contact with the common electrode CE.

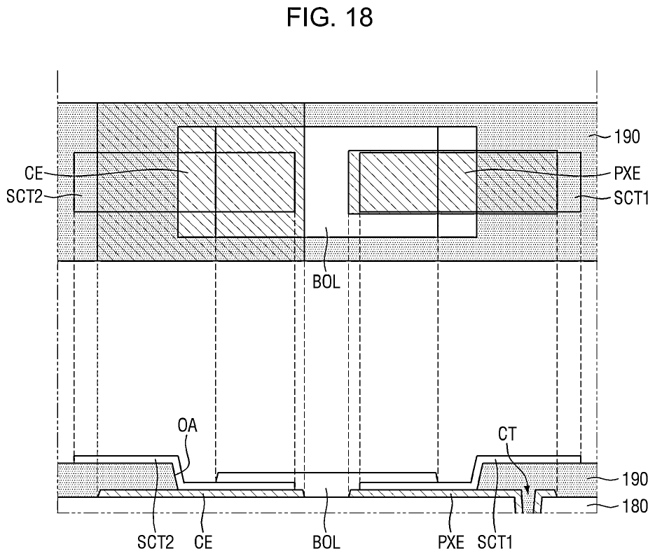

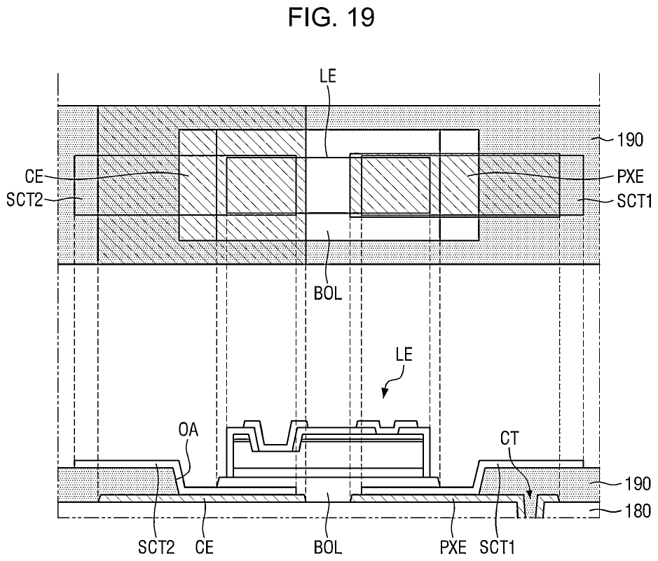

Fourth, as shown in FIGS. 18 and 19, an organic pattern layer BOL is formed on the pixel electrodes PXE and the common electrode CE in the opening OA, and the light-emitting element of the light-emitting element substrate ESUB is fixed to the organic pattern layer BOL (S140 in FIG. 13).

First, the organic pattern layer BOL may be a temporary adhesive layer, and/or a temporary fixation layer that serves to temporarily fix or adhere the plurality of light-emitting elements LE for a process of transferring the plurality of light-emitting elements LE to the display panel 100. The thickness of the organic pattern layer BOL may be less than the height of the opening OA or the thickness of the bank 190.

The organic pattern layer BOL may be a photosensitive organic layer such as photoresist. Alternatively, the organic pattern layer BOL may be formed of acryl resin, epoxy resin, phenolic resin, polyamide resin, polyimide resin, and/or the like.

Then, a plurality of light-emitting elements LE of the light-emitting element substrate ESUB are fixed to the organic pattern layer BOL.

For example, a plurality of light-emitting elements LE of the light-emitting element substrate ESUB may be fixed to the organic pattern layer BOL using a stamp. Here, the stamp may detach the plurality of light-emitting elements LE from the adhesive layer, including an adhesive layer having a higher adhesion than the adhesive layer of the light-emitting element substrate ESUB. Each of the plurality of light-emitting elements LE that are detached from the light-emitting element substrate ESUB and transferred to the stamp may be temporarily fixed by being embedded in the organic pattern layer BOL. At this time, a portion of each of the plurality of light-emitting elements LE may be temporarily fixed by being embedded in the organic pattern layer BOL. For example, the undoped semiconductor layer USEM of each of the plurality of light-emitting elements LE may be embedded and fixed in the organic pattern layer BOL.

When the organic pattern layer BOL is a photosensitive organic layer such as a photoresist, after curing (e.g., soft baking) the organic pattern layer BOL at a first temperature, at least a portion of each of the plurality of light-emitting elements LE may be inserted into the organic pattern layer BOL, and then the organic pattern layer BOL may be fully cured at a second temperature higher than the first temperature. The first temperature may be approximately 100 degrees, and the second temperature may be approximately 230 degrees, but the present disclosure is not limited thereto. In the process of curing the organic pattern layer BOL at the first temperature, the organic pattern layer BOL is fluid because the first temperature is low enough to fully cure the organic patterned layer BOL, which allows the organic pattern layer BOL to spread throughout the opening OA. Furthermore, the process of fully curing the organic pattern layer BOL at the second temperature may be performed for approximately 30 minutes.

Alternatively, because at least a portion of the light-emitting element LE may be inserted and embedded in the organic pattern layer BOL, the organic pattern layer BOL remains between the bottom surface of the light-emitting element LE and the pixel electrode PXE, and between the bottom surface of the light-emitting element LE and the common electrode CE.

Alternatively, if the organic pattern layer BOL has a large fluidity, the organic pattern layer BOL may be pushed to the edge of the opening OA by the light-emitting element LE, in which case the organic pattern layer BOL may be removed between the underside of the light-emitting element LE and the pixel electrode PXE and between the underside of the light-emitting element LE and the common electrode CE, or a very small height of the organic pattern layer BOL may be located. That is, the organic pattern layer BOL may not be located between the bottom surface of the light-emitting element LE and the pixel electrode PXE, and/or between the bottom surface of the light-emitting element LE and the common electrode CE, and/or may be located at a very small height.

Alternatively, if the fluidity of the organic pattern layer BOL is small or the organic pattern layer BOL is hard, the depth at which the light-emitting element LE is inserted or embedded in the organic pattern layer BOL may be very small, or the light-emitting element LE may not be inserted or embedded in the organic pattern layer BOL but may be placed on the organic pattern layer BOL.

Then, by applying heat to the adhesive layer of the stamp to reduce the adhesion of the adhesive layer, the stamp may be separated from the plurality of light-emitting elements LE.

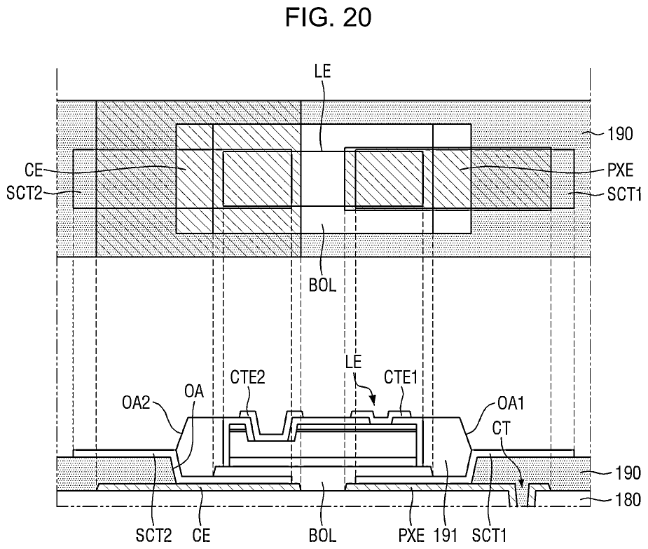

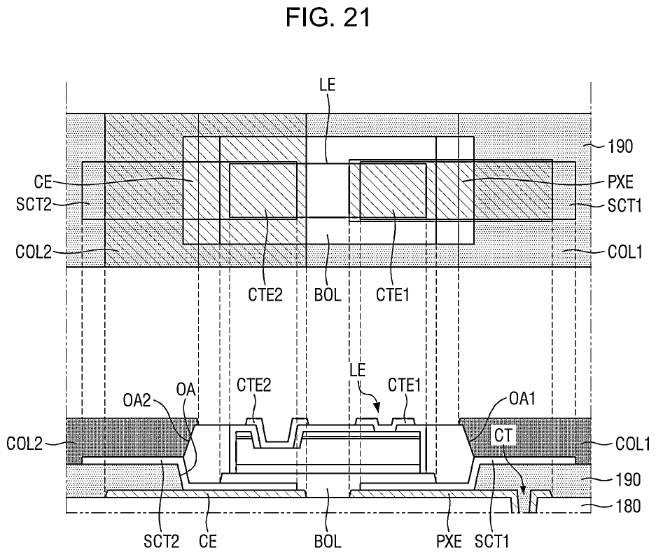

Fifth, as shown in FIGS. 20 and 21, a third organic layer 191, a first conductive wall COL1, and a second conductive wall COL2 are formed (S150 in FIG. 13).

First, the third organic layer 191 having a first electrode opening OA1 and a second electrode opening OA2 is formed. The third organic layer 191 may be formed to cover the bank 190, the first auxiliary electrode SCT1, and the second auxiliary electrode SCT2. The third organic layer 191 may be formed to flatten the step caused by the light-emitting element LE but expose at least some of the light-emitting element LE, for example, the first contact electrode CTE1 and the second contact electrode CTE2.

The first electrode opening OA1 may be formed to overlap the bank 190 and completely penetrate the third organic layer 191 to expose a portion of the first auxiliary electrode SCT1. The second electrode opening OA2 may be formed to overlap the bank 190 and completely penetrate the third organic layer 191 to expose a portion of the second auxiliary electrode SCT2.

As described with reference to FIGS. 9-10, the first electrode opening OA1 and the second electrode opening OA2 may be formed to overlap one surface of the light-emitting element LE. The first surface of the light-emitting element LE and the second surface opposite the first surface completely overlap the first electrode opening OA1 and the second electrode opening OA2, respectively.

Subsequently, the first electrode opening OA1 and the second electrode opening OA2 may be filled with a filling material containing a conductive material to form a first conductive wall COL1 and a second conductive wall COL2. The filling material may include a light-blocking material. For example, the light-blocking material may include an inorganic black pigment such as carbon black and/or an organic black pigment. The light-blocking material may be omitted, but when the first conductive wall COL1 and the second conductive wall COL2 are formed of a filling mater containing a light-blocking material, it is advantageous to prevent light from the light-emitting element LE of one sub-pixel from proceeding to the neighboring sub-pixel.

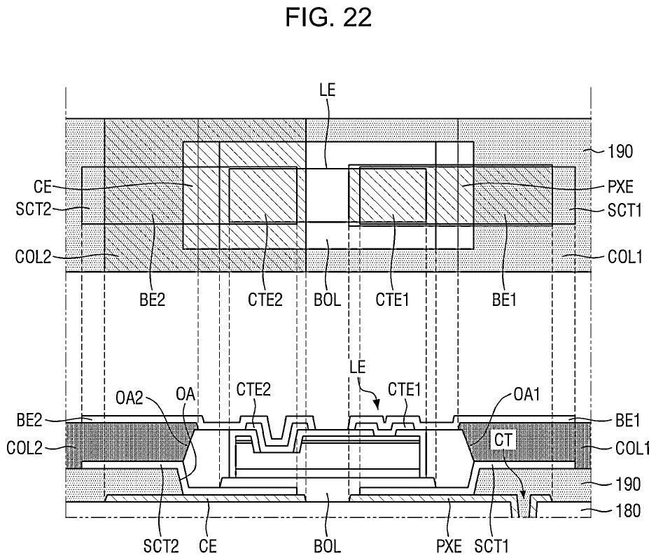

Sixth, as shown in FIG. 22, a first connection electrode BE1 and a second connection electrode BE2 are formed using a photolithography process (S160 in FIG. 13).

The first connection electrode BE1 connects the first contact electrode CTE1 of the light-emitting element LE and the first conductive wall COL1. The second connection electrode BE2 connects the second contact electrode CTE2 of the light-emitting element LE and the common electrode CE.

Then, the light-blocking layer BM and the fourth organic layer 192 are sequentially formed.

A first light-blocking layer BM1 of the light-blocking layer BM may be formed on the bank 190, and a second light-blocking layer BM2 of the light-blocking layer BM may be formed on the first light-blocking layer BM1.

In FIG. 8, it is illustrated that a length of the bottom surface of the second light-blocking layer BM2 in the first direction DR1 is shorter than a length of the top surface of the first light-blocking layer BM1 in the first direction DR1, so that a step is formed extending to the side of the first light-blocking layer BM1, a portion of the top surface of the first light-blocking layer BM1, and the side of the second light-blocking layer BM2, the present disclosure is not limited thereto. For example, the length of the bottom surface of the second light-blocking layer BM2 in the first direction DR1 is substantially the same as the length of the top surface of the first light-blocking layer BM1 in the first direction DR1, such that the side of the first light-blocking layer BM1 and the side of the second light-blocking layer BM2 may be connected without the above step. Alternatively, the length in the first direction DR1 of the bottom surface of the second light-blocking layer BM2 is substantially the same as the length in the first direction DR1 of the top surface of the first light-blocking layer BM1, but the angle at which the side of the first light-blocking layer BM1 is inclined relative to the bottom side of the first light light-blocking layer BM1 and the angle at which the side of the second light-blocking layer BM2 is inclined relative to the bottom side of the second light-blocking layer BM2 may be different. When reducing or eliminating the step, it is possible to reduce, prevent, or minimize the occurrence of uneven light reflection, such as light leakage, due to diffuse reflection of light.

The fourth organic layer 192 may be formed to cover the light-emitting element LE in an area partitioned by the light-blocking layer BM.

Then, as shown in FIG. 8, a first wavelength conversion layer QDL1, a second wavelength conversion layer QDL2, and a light transmission layer are formed on the fourth organic layer 192 and color filters CF1, CF2, and CF3 are formed on the first wavelength conversion layer QDL1, the second wavelength conversion layer QDL2, and the light transmission layer TPL in the area partitioned by the light-blocking layer BM.

First, a first capping layer CAP1 is formed covering the light-emitting element layer EML and the light-blocking layer BM, and a reflective layer RF is formed on the first capping layer CAP1 located on the side of the light-blocking layer BM.

Then, among the areas partitioned by the light-blocking layer BM, the first light conversion layer QDL1 is formed in the area corresponding to the first sub-pixel SPX1, the second light conversion layer QDL2 is formed in the area corresponding to the second sub-pixel SPX2, and the light transmission layer TPL is formed in the area corresponding to the fourth sub-pixel SPX4.

Then, a second capping layer CAP2 is formed on the first capping layer CAP1, the first light conversion layer QDL1, the second light conversion layer QDL2, and the light transmission layer TPL, and a fourth organic layer 192 is formed on the second capping layer CAP2.

Then, a plurality of color filters CF1, CF2, and CF3 are formed on the fourth organic layer 192, and a fifth organic layer 193 is formed on the plurality of color filters CF1, CF2, and CF3.

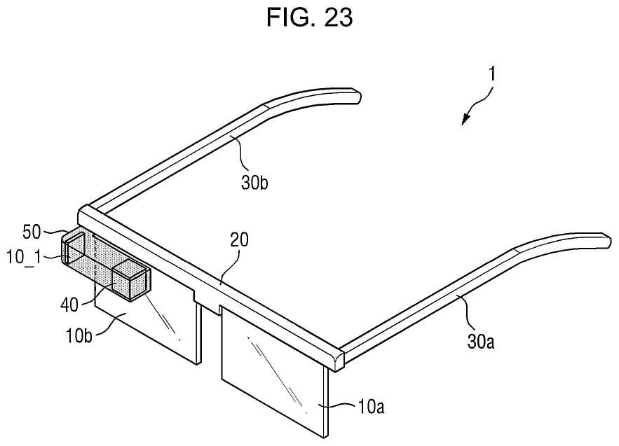

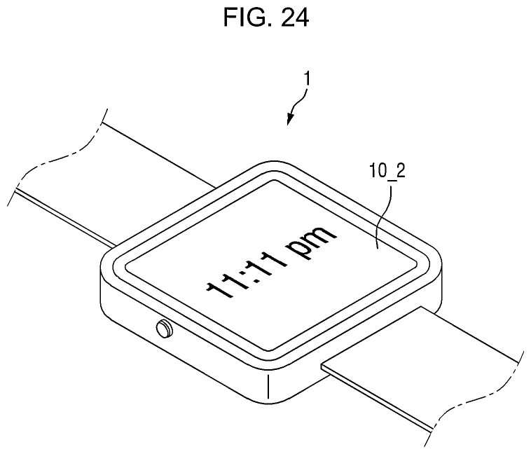

FIG. 23 illustrates a virtual reality device 1 in which the display device 10 is included according to one or more embodiments is used.

Referring to FIG. 23, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 23 illustrates the virtual reality device 1 including the two legs 30a and 30b. However, the present disclosure is not limited thereto. The virtual reality device 1 according to one or more embodiments may be used in a head-mounted display including a head-mounted band that may be mounted on a user's head, instead of including the legs 30a and 30b. For example, the virtual reality device 1 according to one or more embodiments may not be limited to the example shown in FIG. 23, and may be applied in various forms and in various electronic devices.

FIG. 23 illustrates that the display device housing 50 is located at a right end of the support frame 20. However, the present disclosure is not limited thereto. For example, the display device housing 50 may be located at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be located at each of the left end and the right end of the support frame 20. In this case, the user may view the virtual reality image displayed on the display device 10 via both the left eye and the right eye.

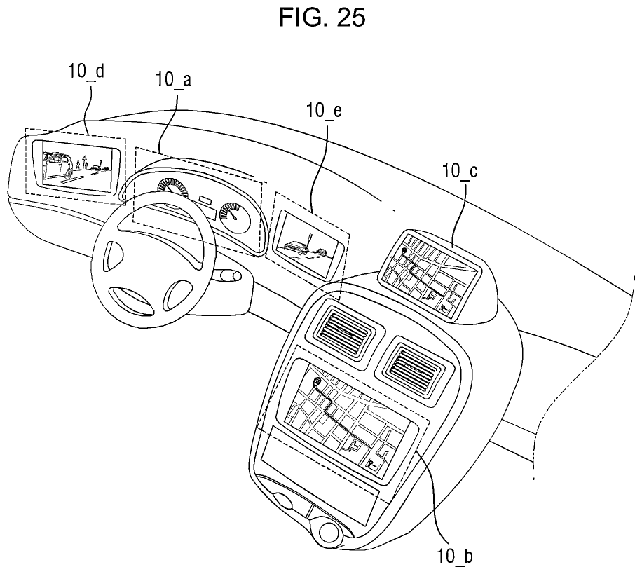

FIG. 24 illustrates a smart device including a display device according to one or more embodiments.

Referring to FIG. 24, a display device 10 according to one or more embodiments may be applied to a smart watch 2 as one of smart devices.

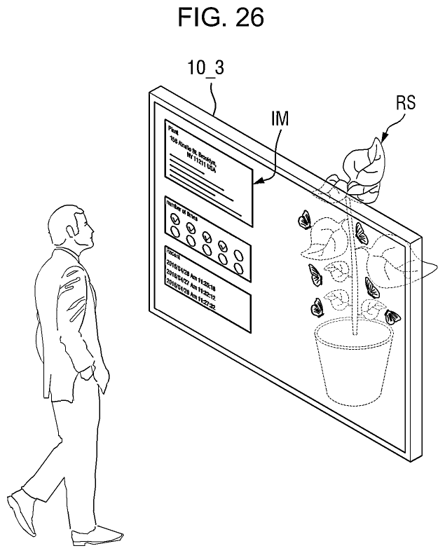

FIG. 25 illustrates a vehicle in which display devices according to one or more embodiments are used.

Referring to FIG. 25, the display devices 10_a, 10_b, or 10_c according to one or more embodiments may be respectively applied to the dashboard of the vehicle, applied to the center fascia of the vehicle, or applied to a Center Information Display (CID) located on the dashboard of the vehicle. Further, each of the display devices 10_d and 10_e according to one or more embodiments may be applied to each mirror display that replaces each of side-view mirrors of the vehicle.

FIG. 26 is an example diagram illustrating a transparent display device including a display device according to one or more embodiments.

Referring to FIG. 26, a display device according to one or more embodiments may be applied to a transparent display device. The transparent display device may transmit light therethrough while displaying an image IM thereon. Therefore, a user located in front of the transparent display device may not only view the image IM displayed on the display device 10, but also may view an object RS or a background located in rear of the transparent display device. In case that the display device 10 is applied to the transparent display device, the substrate SUB of the display device 10 shown in FIG. 8 may include a light-transmitting portion that may transmit light therethrough or may be made of a material that may transmit light therethrough.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

However, the aspects of the present disclosure are not restricted to the one set forth herein. The above and other aspects of the present disclosure will become more apparent to one of ordinary skill in the art to which the present disclosure pertains by referencing the claims, with functional equivalents thereof to be included therein.

What is claimed is:

1. A light-emitting element device comprising:
a substrate;
a pixel electrode and a common electrode spaced from each other on the substrate;
an organic pattern layer between the pixel electrode and the common electrode;
a light-emitting element above the organic pattern layer and comprising a first contact electrode and a second contact electrode on a top surface of the light-emitting element;
an organic layer located in an area excluding an area where the light-emitting element is located and have a first opening and a second opening;
a first conductive wall in the first opening, and electrically connected to the pixel electrode;
a second conductive wall in the second opening, and electrically connected to the common electrode; and
a first connection electrode connected to the first contact electrode of the light-emitting element and the first conductive wall, and a second connection electrode connected to the second contact electrode of the light-emitting element and the second conductive wall.

2. The light-emitting element device of claim 1, further comprising:
a bank covering edges of the pixel electrode and the common electrode and in an area excluding an area where the organic pattern layer is located;
a first auxiliary electrode extending from the pixel electrode above a top surface of the bank; and
a second auxiliary electrode extending from the common electrode above the top surface of the bank,
wherein the first opening exposes the first auxiliary electrode, and
wherein the second opening exposes the second auxiliary electrode.

3. The light-emitting element device of claim 2, wherein the first conductive wall is in contact with the first auxiliary electrode through the first opening, and
wherein the second conductive wall is in contact with the second auxiliary electrode through the second opening.

4. The light-emitting element device of claim 3, wherein the first conductive wall and the second conductive wall comprise a light-blocking material.

5. The light-emitting element device of claim 4, wherein the first conductive wall overlaps a first side of the light-emitting element, and the first side of the light-emitting element completely overlaps the first conductive wall,
wherein the second conductive wall overlaps a second side of the light-emitting element, and the second side of the light-emitting element completely overlaps the second conductive wall, and
wherein the first side and the second side are parallel to each other.

6. The light-emitting element device of claim 5, wherein a width of the first conductive wall is greater than a width of the first side of the light-emitting element, and
wherein a width of the second conductive wall is greater than a width of the second side of the light-emitting element.

7. The light-emitting element device of claim 5, wherein the first conductive wall overlaps a third side of the light-emitting element and is spaced from the second conductive wall,
wherein the second conductive wall overlaps a fourth side of the light-emitting element and is spaced from the first conductive wall, and
wherein the third side is substantially perpendicular to the first side and parallel to the fourth side.

8. The light-emitting element device of claim 5, further comprising:
a third conductive wall that overlaps a third side of the light-emitting element, and that is spaced from the first conductive wall and the second conductive wall, and
a fourth conductive wall that overlaps a fourth side of the light-emitting element, and that is spaced from the first conductive wall and the second conductive wall,
wherein the third side of the light-emitting element completely overlaps the third conductive wall,
wherein the fourth side of the light-emitting element completely overlaps the fourth conductive wall, and
wherein the third side is substantially perpendicular to the first side and parallel to the fourth side.

9. The light-emitting element device of claim 1, wherein the light-emitting element further comprises a third semiconductor layer, a second semiconductor layer, an active layer, a first semiconductor layer, and a protective layer,
wherein the third semiconductor layer is in contact with the organic pattern layer, and
wherein the protective layer is on an entire surface of the light-emitting element, excluding a bottom of the light-emitting element, and defines an opening exposing the first contact electrode and the second contact electrode on the top surface of the light-emitting element.

10. The light-emitting element device of claim 1, wherein the pixel electrode and the common electrode comprise an opaque metal material, and
wherein the first connection electrode and the second connection electrode comprise a transparent conductive oxide.

11. The light-emitting element device of claim 1, wherein a width of the organic pattern layer is greater than a width of the light-emitting element.

12. The light-emitting element device of claim 2, further comprising:
a light-blocking layer on the first connection electrode and the second connection electrode, overlapping the bank, and defining a light-emitting area; and
a wavelength conversion layer or a light transmission layer in a space defined by the light-blocking layer.

13. The light-emitting element device of claim 12, further comprising a capping layer, an overcoat layer, and a color filter layer sequentially above the wavelength conversion layer and the light-blocking layer.

14. A method of manufacturing a display device comprising:
forming a pixel electrode and a common electrode spaced from each other on a substrate;
forming a bank defining an opening exposing a portion of the pixel electrode and the common electrode;
forming a first auxiliary electrode above a top surface of the bank along the opening on a top surface of the pixel electrode;
forming a second auxiliary electrode above the top surface of the bank along the opening on a top surface of the common electrode;
forming an organic pattern layer between the first auxiliary electrode and the second auxiliary electrode;
bonding a light-emitting element on the organic pattern layer;
exposing a first contact electrode and a second contact electrode above a top surface of the light-emitting element;
flattening the light-emitting element,
forming an organic layer defining a first opening exposing the first auxiliary electrode, and a second opening exposing the second auxiliary electrode;
forming a first conductive wall by filling the first opening with a conductive material;
forming a second conductive wall by filling the second opening with the conductive material;
forming a first connection electrode connected to the first contact electrode of the light-emitting element and the first conductive wall; and
forming a second connection electrode connected to the second contact electrode of the light-emitting element and the second conductive wall.

15. The method of claim 14, wherein the conductive material further comprises a light-blocking material.

16. The method of claim 14, wherein a width of the first conductive wall is greater than a width of a first side of the light-emitting element, and
wherein a width of the second conductive wall is greater than a width of a second side of the light-emitting element.

17. The method of claim 14, wherein the pixel electrode and the common electrode comprise an opaque metal material, and
wherein the first connection electrode and the second connection electrode comprise a transparent conductive oxide.

18. The method of claim 14, further comprising:
forming a light-blocking layer on the bank;
forming a first wavelength conversion layer in an area corresponding to a first sub-pixel of the display device;
forming a second wavelength conversion layer in an area corresponding to a second sub-pixel of the display device;
forming a light transmission layer in an area corresponding to a third sub-pixel of the display device from among the areas partitioned by the light-blocking layer;
forming a first color filter on the first wavelength conversion layer;
forming a second color filter on the second wavelength conversion layer; and
forming a third color filter on the light transmission layer.

19. The method of claim 14, wherein the bonding the light-emitting element on the organic pattern layer further comprises:
curing the organic pattern layer in the opening at a first temperature;
inserting a portion of each of the light-emitting elements into the organic pattern layer at the opening; and
curing the organic pattern layer at a second temperature higher than the first temperature.

20. The method of claim 19, wherein the light-emitting element further comprises a third semiconductor layer, a second semiconductor layer, an active layer, a first semiconductor layer, and a protective layer, and
wherein the third semiconductor layer is inserted into the organic pattern layer.

21. Electronic device comprising:
a display device including a light-emitting elements and displays an image,
the light-emitting elements includes,
a substrate;
a pixel electrode and a common electrode spaced from each other on the substrate;
an organic pattern layer between the pixel electrode and the common electrode;
a light-emitting element above the organic pattern layer and comprising a first contact electrode and a second contact electrode on a top surface of the light-emitting element;
an organic layer located in an area excluding an area where the light-emitting element is located and have a first opening and a second opening;
a first conductive wall in the first opening, and electrically connected to the pixel electrode;
a second conductive wall in the second opening, and electrically connected to the common electrode; and
a first connection electrode connected to the first contact electrode of the light-emitting element and the first conductive wall, and a second connection electrode connected to the second contact electrode of the light-emitting element and the second conductive wall.
